(19) United States
(12) Patent Application Publication
(10) Pub. No.: US 2025/0172613 A1
(43) Pub. Date: May 29, 2025

(54) TEST ARRANGEMENT FOR OVER-THE-AIR TESTING AN ANGLED DEVICE UNDER TEST USING A CARRIER STRUCTURE WITH AN OPENING

(71) Applicant: Advantest Corporation, Tokyo (JP)

(72) Inventors: José MOREIRA, Stuttgart (DE); Hiromitsu TAKASU, Tokyo (JP); Natsuki SHIOTA, Tokyo (JP); Aritomo KIKUCHI, Tokyo (JP); Yasuyuki KATO, Tokyo (JP); Hiroyuki MINEO, Tokyo (JP)

(21) Appl. No.: 19/038,983

(22) Filed: Jan. 28, 2025

Related U.S. Application Data
(63) Continuation of application No. PCT/EP2023/059653, filed on Apr. 13, 2023.

(30) Foreign Application Priority Data
Jul. 29, 2022 (EP) 22 187 978.6

(51) Int. Cl. G01R 31/319; G01R 1/04; G01R 29/10; G01R 31/28

(52) U.S. Cl. CPC G01R 31/31905; G01R 1/045; G01R 29/10; G01R 31/2896

(57) ABSTRACT

The invention relates to a test arrangement for over-the-air testing an angled device under test, wherein the test arrangement comprises a carrier structure and a device-under-test socket which is coupled to the carrier structure. The device-under-test socket is configured to establish an electrical contact with an inner surface of the angled device under test or with a connector which is arranged on the inner surface of the angled device under test. The carrier structure comprises an opening extending away from the device-under-test socket in a direction of an outward surface normal of a first outer surface of the angled device-under-test.

### CROSS-REFERENCE TO RELATED APPLICATIONS

This application is a continuation of copending International Application No. PCT/EP2023/059653, filed Apr. 13, 2023, which is incorporated herein by reference in its entirety, and additionally claims priority from European Application No. EP 22187978.6, filed Jul. 29, 2022, which is also incorporated herein by reference in its entirety.

Embodiments according to the invention relate to a test arrangement for over-the-air testing, in particular using a carrier structure with an opening.

Embodiments according to the invention relate to a socket for over the air testing of L-shaped antenna in Package modules with automated test equipment.

### BACKGROUND OF THE INVENTION

Test arrangements can be used to test devices under test (e.g., an antenna in package device) that are capable of receiving and/or emitting electromagnetic radiation. Commonly a device under test has a flat shape with two opposite surfaces such that, for example, the device under test can be mounted in a device-under-test socket (e.g., an over the air (OTA) socket for radiating near field testing of antenna-in-package devices) such that one of the surfaces faces the device-under-test socket and the other surface faces away from the device-under-test socket. For example, one may orient the device under test such that a surface of the device under test with an antenna faces away from the device-under-test socket.

However, the shape of the device under test may not be planar. For example, the device under test may have an angular shape such as an L-shape. Furthermore, an angled device may be configured to emit and/or receive electromagnetic radiation at at least one outer surface. For example, an angular shaped device under test may have one or more antenna arrays (or other antennas) on one or two outer surfaces. As a result, flexibility regarding available orientations of the outer surfaces of the device under test may be reduced. For example, arranging an angular test device in a socket may need specific orientations in order to accommodate to the shape. Furthermore, when one outer surface is oriented to face away from a carrier structure supporting a socket, another outer surface may have to be oriented at an angle relative to the carrier structure. However, the carrier structure may cause interferences in electromagnetic radiation received by and/or emitted by the outer surfaces. The interferences may increase when an outer surface is oriented at an angle relative to the carrier structure.

An angled device under test poses challenges in regards to orientation of the device under test and interference with the carrier structure which can affect testing efficiency, accuracy and reproducibility.

Therefore, there is a need for a test arrangement that improves a compromise between testing efficiency, accuracy and reproducibility.

### SUMMARY

An embodiment may have a test arrangement for over-the-air testing an angled device under test, wherein the test arrangement includes a carrier structure; wherein the test arrangement includes a device-under-test socket which is coupled to the carrier structure, wherein the device-under-test socket is configured to establish an electrical contact with an inner surface of the angled device under test or with a connector which is arranged on the inner surface of the angled device under test, and wherein the carrier structure includes an opening extending away from the device-under-test socket in a direction of an outward surface normal of a first outer surface of the angled device-under-test.

Another embodiment may have a test arrangement for over-the-air testing an angled device under test, wherein the test arrangement includes a carrier structure; wherein the test arrangement includes a device-under-test socket which is coupled to the carrier structure, wherein the device-under-test socket is configured to establish an electrical contact with an inner surface of the angled device under test or with a connector which is arranged on the inner surface of the angled device under test, and wherein the device-under-test socket is configured to position the angled device-under-test such that a surface normal of a first outer surface of the angled device-under-test is parallel, within a tolerance of +/−15 degrees, to the surface of the loadboard, and such that a second outer surface of the angled device under test is facing away from the loadboard, and such that a surface normal of the second outer surface of the angled device-under-test is perpendicular, within a tolerance of +/−15 degrees, to the surface of the loadboard;

wherein the carrier structure includes an opening extending away from the device-under-test socket in a direction of an outward surface normal of the first outer surface of the angled device-under-test.

An embodiment of the invention is directed at a test arrangement for over-the-air testing an angled (e.g. L-shaped) device under test (e.g. a L-shape Antenna-in-package device under test), wherein the test arrangement comprises a carrier structure (e.g. a PCB test fixture or a loadboard), wherein the test arrangement comprises a device-under-test socket which is coupled to the carrier structure (e.g. the PCB test fixture or the load board) (e.g. directly or with an extender assembly and/or a PCB interposer in between the carrier structure and the device-under-test socket), wherein the device-under-test socket is configured to establish an electrical contact with an inner surface of the angled (e.g. L-shaped) device under test (e.g. with an inner surface of the angled device under test which is opposite to a second outer surface of the angled device under test) or with a connector which is arranged on the inner surface of the angled (e.g. L-shaped) device under test, and wherein the carrier structure (e.g. the test fixture PCB or the load board) comprises an opening (e.g. a hole or a cutout) extending away from the device-under-test socket in a direction of an outward surface normal of a first outer surface of the angled device-under-test (e.g. away from the device-under test socket in a main radiation direction of an antenna structure on the first outer surface of the device-under-test).

The device-under-test socket allows coupling the angled device under test with the test arrangement. Furthermore, the electrical contact allows transmission of at least one of electrical power, one or more control signals, one or more measurement signals, or generally one or more electrical or optical signals between the test arrangement and the device under test coupled to the device-under-test socket.

The opening of the carrier structure reduces interferences of an electromagnetic field emitted by or received by the device under test (when coupled to the device-under-test socket). Since the opening extends away in a direction of the outward surface normal of a first outer surface of the angled device-under-test, interference with an electromagnetic field emitted by or received by the first outer surface of the angled device under test is reduced. As a result, flexibility in selection of the orientation of the first outer surface is increased. Furthermore, the opening can be configured to receive at least a part of at least one of the device-under-test socket, the device under test, and an antenna structure for testing the first outer surface. Therefore, at least a part of the transmission of electromagnetic waves between the first outer surface and the antenna structure may occur within the opening (and therefore with reduced interference). Moreover, it should be noted that such an arrangement allows for an implementation of the test arrangement with a small construction height. For example, by providing an opening in the carrier structure, it is not necessary to have a large spacing between the device under test and the carrier structure. Rather, the device under test may be placed close to the plane of the carrier structure or even reach into the plane of the carrier structure. Accordingly, the design is particularly advantageous in situations in which a spacing between the carrier structure and a handler is very limited. Furthermore, the arrangement is well-suited for testing devices under test having two antennas on two sides, since an antenna which is substantially parallel to the carrier structure may be placed closer to the carrier structure when compared to conventional socket arrangements, which leaves more space between said device under test antenna and an associated test antenna without increasing a needed height of an overall arrangement including the test antenna. The other antenna which may be substantially perpendicular to the carrier structure may still be well testable since the opening in the carrier structure, which may be arranged in a main radiation direction of said further antenna or next to the main radiation direction of said further antenna reduces and falsification of measurement result.

To conclude, the test arrangement allows for an over-the-air testing of an angled device under test using a relatively small space while providing good accuracy by reducing an impact of the carrier structure.

The test arrangement may be used for near field testing, e.g., of antenna in package devices. The test arrangement may be used for testing electromagnetic waves of a 5G frequency band.

According to an embodiment, the device-under-test socket is configured to position the angled device-under-test such that a surface normal of a first outer surface of the angled (e.g. L-shaped) device-under-test is parallel, within a tolerance of +/−15 degrees, to the surface (e.g. main surface) of the carrier structure (e.g., of the loadboard).

The first outer surface may therefore receive and/or emit electromagnetic radiation in a direction arranged predominantly parallel to the surface of the carrier structure. The interference of the carrier structure is consequently reduced by the opening in the carrier structure and changes less along a transmission path of an electromagnetic wave. Furthermore, such an orientation allows a second outer surface to face away from the carrier structure, therefore reducing interference for the second outer surface as well.

According to an embodiment, the device-under-test socket is configured to position the angled device-under-test such that a second outer surface of the angled (e.g. L-shaped) device under test (e.g. a surface comprising a radiating structure) is facing away from the carrier structure (e.g., loadboard), and such that a surface normal of the second outer surface of the angled (e.g. L-shaped) device-under-test is perpendicular, within a tolerance of +/−15 degrees, to the surface of the carrier structure (e.g., loadboard).

Since the second outer surface essentially faces away from the carrier structure, interferences with the carrier structure are reduced. Moreover, a test antenna can be placed and aligned opposite to the second outer surface in an efficient manner.

According to an embodiment, the opening is a hole extending through a full thickness of the carrier structure.

The opening therefore realizes a through hole, which further lowers interferences. For example, using a hole extending through the full thickness of the carrier structure, the device under test can be placed in such a manner that a radiation from the first outer surface (or even a significant lobe of the antenna located on the first outer surface of the device under test) extends into a plane of the carrier structure (at least in an area of the carrier structure in which the opening is located). Thus, the device under test may even extend into the opening of the carrier structure in some cases. This allows for a very compact test arrangement. On the other hand, an accurate measurement result can even be obtained if a significant lobe (e.g. the main lobe or a strong side lobe) or a significant near field component of the antenna located on the first outer surface of the device under test) extends into a plane of the carrier structure.

Moreover, the opening may, for example, give access (e.g., in form of a possibility to route one or more electric cables) to devices (e.g., a signal source and/or a signal receiver) on a side of the carrier structure facing away from the device-under-test socket.

According to an embodiment, an extension of the opening in a direction of an outward surface normal of the first outer surface of the angled device-under-test (e.g. away from the device-under test socket in a main radiation direction of an antenna structure on the first outer surface of the device-under-test) is at least 2 wavelengths or at least 3 wavelengths or at least 4 wavelengths (e.g. free-space wavelengths, or wavelengths in a medium between the first outer surface of the angled device under test and the carrier structure) at a lowest frequency of operation of the angled device under test (e.g. at a lowest frequency of operation of an Antenna-in-Package (AiP) module that makes up the device under test or that is included in the device under test).

It has been found that interferences with the carrier structure reduce significantly with an opening with dimensions as defined above. Propagation of electromagnetic waves within the opening may be improved. For example, the opening may cover the full nearfield region of the antenna arranged on the first outer surface of the device under test (or at least 60% or at least 80% of the nearfield region) and/or may even cover a part of the farfield region (e.g. with a distance from the antenna larger than 2D²/A, wherein D is a longitude or diameter of the antenna) of the antenna arranged on the first outer surface of the device under test. Accordingly, a distortion of an antenna characteristic of the antenna arranged on the first outer surface of the device under test by the carrier structure may be small due to the presence of the opening.

According to an embodiment, an extension of the opening in a direction perpendicular to an outward surface normal of the first outer surface of the angled device-under-test (e.g. a width of the opening in a direction parallel to the first outer surface) is larger than an extension of a radiating structure on the first outer surface of the device under test (or even larger than two times the extension of the radiating structure, or even larger than three times the extension of the radiating structure), or an extension of the opening in a direction perpendicular to an outward surface normal of the first outer surface of the angled device-under-test (e.g. a width of the opening in a direction parallel to the first outer surface) is larger than an extension of the device under test (or even larger than two times the extension of the device under test, or even larger than three times the extension of the device under test).

Since the extension (e.g. the lateral extension or “width”) of the opening is larger than the radiating structure or the device under test, interferences from walls of the opening at the end of the extension may be reduced. For example, by choosing an appropriately large extension of the opening, it can be achieved that the opening may cover the full nearfield region of the antenna arranged on the first outer surface of the device under test (or at least 60% or at least 80% of the nearfield region). Accordingly, an impact of the carrier structure can be kept small, even if a distance between the device under test and a plane of the carrier structure is small or if the device under test reaches into the plane of the carrier structure.

According to an embodiment, an extension of the opening is chosen such that a distance between an edge of the angled device under test or an edge of an antenna-in-package device and the carrier structure is at least one wavelength (e.g. a free-space wavelength, or a wavelength in a medium between the first outer surface of the angled device under test and the carrier structure) at a lowest frequency of operation of the angled device under test (e.g. at a lowest frequency of operation of an Antenna-in-Package (AiP) module that makes up the device under test or that is included in the device under test) (while there is no material of the carrier structure within a distance of one wavelength from the edge of the angled device under test or from the edge of the antenna-in-package device).

It has been recognized that effects on emission and/or reception (e.g., beamforming, reflections, formation of standing waves, and interferences) of one or more antennas that may be arranged on the first outer surface and that may be caused by the carrier structure are significantly reduced at such distance. Moreover, such a distance can easily be provided by providing the opening in the carrier structure, while keeping dimensions of a test arrangement reasonably small.

According to an embodiment, the device under test socket is configured such that at least a portion of the device under test is located in the opening when the device under test is inserted in the device under test socket (wherein, for example, a device-under-test location of the test socket extends into the opening).

The size of a test arrangement can be kept reasonably small using such an arrangement, while the device under test is arranged at a region with sufficiently small interference with the carrier structure.

According to an embodiment, the device under test socket is configured such that the device under test socket extends into the opening (wherein, for example, a device-under-test location of the device under test socket extends into the opening).

The device-under-test socket therefore allows inserting a device under test relatively deep into the opening. The device-under-test socket therefore has greater compatibility with different sizes for the device under test and provides more options for positioning the device under test within the opening. Also, a relatively small construction height can be achieved in this manner, which allows the usage of the test arrangement in situations in which there is a small spacing between a handler and the device-under test socket without compromising the performance.

According to an embodiment, the test arrangement comprises a first antenna or antenna structure (e.g. a single aperture antenna (e.g. dual linear polarized or circular polarized)) configured to receive a signal radiated from the first outer surface of the angled device under test and/or configured to emit a signal to be received at the first outer surface of the angled device.

The first antenna or antenna device allows establishing an over the air connection with a device under test in the device-under-test socket. Therefore, the first antenna or antenna structure allows testing the device under test. The device-under-test socket allows orienting the device under test in a defined way such that the first antenna or antenna structure can be accurately oriented relative to the angled device under test. The opening in the carrier structure allows for a relatively undistorted wireless connection between an antenna on the first outer surface of the device under test and the first antenna or antenna structure.

According to an embodiment, the test arrangement comprises a first antenna or antenna structure (e.g. a single aperture antenna (e.g. dual linear polarized or circular polarized)), wherein an aperture of the first antenna or antenna structure is arranged at a distance from the first outer surface of the angled device under test, such that a surface normal of the first outer surface of the angled device under test extends through the aperture of the first antenna or antenna structure (at least when the second antenna or antenna structure is placed at an operation position).

It has been recognized that a design of the device under test socket may allow to carry a device under test such that a surface normal of the first outer surface of the device under test may extend through the aperture of the first antenna or antenna structure. The first outer surface (or an antenna structure on the first outer surface of the device under test) may be configured to emit and/or receive (e.g., by beamforming) such that a main lobe is in a direction perpendicular to the first outer surface. Accordingly, by arranging the device under test socket and the first antenna such that the surface normal of the first outer surface of the device under test extends through the aperture of the first antenna or antenna structure, wireless communication between the device under test and the first antenna or antenna structure or, generally speaking, wireless testing of the device under test using the first antenna or antenna structure may be improved.

According to an embodiment, the first antenna or antenna structure is at least partly arranged in the opening (e.g. in an open area surrounded by the carrier structure; e.g. in a plane of the carrier structure).

The opening increases a range in a direction perpendicular to the surface of the carrier structure in which the first antenna structure can be arranged. Therefore, the carrier structure is compatible with different first antenna structures. Furthermore, if the device under test is placed at least partially inside the opening, a transmission path between the first antenna structure and the device under test can be arranged at least partially within the opening. As a result, decreased construction height of the test arrangement can be reduced without significantly degrading testing results.

According to an embodiment, a radiating aperture of the first antenna or antenna structure is at least partly arranged in the opening (e.g. in an open area surrounded by the carrier structure; e.g. in a plane of the carrier structure).

Such an arrangement of the radiation aperture allows an electromagnetic wave emitted and/or received at the radiating aperture to travel at least partially within in the opening. Consequently, a spacing between the carrier structure and a handler can be kept small and distortions e.g. by the handler (which may be moveable at a distance from the carrier structure) can be kept within tolerable limits.

According to an embodiment, the first antenna or antenna structure is mounted to have a fixed position with respect to the device under test socket.

Such a fixed position allows repeated coupling and testing of a plurality of angled devices under test such that the plurality of angled device under tests have an equal or similar geometrical relationship to the first antenna or antenna structure. As a result, accuracy and reproducibility of the testing may be improved.

According to an embodiment, the first antenna or antenna structure is mechanically attached to an arm of a handler (which is configured to insert the angled device under test into the device under test socket), such that the first antenna or antenna structure is moveable (wherein the first antenna or antenna structure is at least partly arranged in the opening when the handler pushes the angled device under test into the test socket).

The arm allows the first antenna or antenna structure to be movable, which enables removal of the first antenna or antenna structures (e.g., for easier coupling of the angled device under test to the device-under-test socket) or readjustment of the first antenna or antenna structures. In the case of the handler being configured to insert the angled device under test into the device-under-test socket, the handler facilitates coupling and positioning the first antenna or antenna structure during coupling of the angled device under test to the device-under-test socket. For example, the first antenna or antenna structure may be in a fixed positional relationship with a pusher pushing the device under test into the device under test socket. As an example, the pusher may be directly connected to the first antenna or antenna device. Thus, accordingly, a very stable and well-reproducible positional alignment between the first antenna or antenna structure and the device under test may be reached.

According to an embodiment, the first antenna or antenna structure is configured to be connected with a signal source and/or with a signal receiver via a blind-mating microwave connection (e.g. via a blind mating (hollow) waveguide connection) when the handler has placed the first antenna or antenna structure in an operating position (or, equivalently, when the handler has inserted the angled device under test into the test socket, or when the handler pushes the device under test into the test socket).

The signal source enables the first antenna or antenna structure to emit a signal (e.g., to be received by an antenna array of the angled device under test) and/or the signal receiver allows to evaluate a received signal (e.g., emitted by an antenna or antenna array of the angled device under test and received by the first antenna or antenna structure), and therefore both the signal source and the signal receiver facilitate testing of the angled device under test. The blind-mating microwave connection facilitates (e.g., manual and/or automatic) coupling between the signal source and/or the signal receiver and the first antenna or antenna structure. Accordingly, an efficient test is possible, even in configurations in which the first antenna or antenna structure is moveable (as outlined above).

According to an embodiment, the test arrangement comprises a second antenna or antenna structure (e.g. a single aperture antenna (e.g. dual linear polarized or circular polarized)) configured to receive a signal radiated from a or the second outer surface of the angled device under test and/or to emit a signal to be received at the second outer surface of the angled device under test (at least when the second antenna or antenna structure is placed at an operation position) (or, equivalently, when the handler has inserted the angled device under test into the test socket, or when the handler pushes the device under test into the test socket).

The second antenna or antenna structure allows testing an antenna structure on the second outer surface of the device under test. The second antenna or antenna structure benefits from an orientation of the second outer surface defined by the device-under-test socket. The first and second antenna or antenna structure can perform a testing of the device under test using signals emitted and/or received by antennas or antenna structures on the first and second outer surface of the device under test (e.g., simultaneously or successively) without having to recouple the angled device under test at a different orientation (e.g., or in a different device-under-test socket). Thus, a high testing throughput can be reached.

According to an embodiment, the test arrangement comprises a second antenna or antenna structure (e.g. a single aperture antenna (e.g. dual linear polarized or circular polarized)), wherein an aperture of the second antenna or antenna structure is arranged at a distance from a or the second outer surface of the angled device under test such that a surface normal of the second outer surface of the angled device under test extends through the aperture of the second antenna or antenna structure (at least when the second antenna or antenna structure is placed at an operation position) (or, equivalently, when the handler has inserted the angled device under test into the test socket, or when the handler pushes the device under test into the test socket).

It has been recognized that a design of the device under test socket may allow to carry a device under test such that a surface normal of the second outer surface of the device under test may extend through the aperture of the second antenna or antenna structure. The second outer surface (or an antenna structure on the second outer surface of the device under test) may be configured to emit and/or receive (e.g., by beamforming) such that a main lobe is in a direction perpendicular to the second outer surface. Accordingly, by arranging the device under test socket and the second antenna or antenna structure such that a surface normal of the second outer surface of the device under test extends through the aperture of the second antenna or antenna structure, wireless communication between the device under test and the second antenna or antenna structure or, generally speaking, wireless testing of the device under test using the second antenna or antenna structure may be improved.

According to an embodiment, the second antenna or antenna structure is mechanically attached to an arm of a handler (which is configured to insert and/or push the angled device under test into the device under test socket), such that the second antenna or antenna structure is moveable. The first and second antennas or antenna structures may, for example, be attached to the same/common handler or may each be attached an individual handler.

The arm allows the second antenna or antenna structure to be movable, which enables removal of the second antenna or antenna structures (e.g., for easier coupling of the angled device under test to the device-under-test socket) or readjustment of the second antenna or antenna structures. In the case of the handler being configured to insert the angled device under test into the device-under-test socket, the handler facilitates coupling and positioning the first antenna or antenna structure during coupling of the angled device under test to the device-under-test socket. In case of a common handler, the first and second antenna structures may be arranged in a pre-determined orientation for facilitating orientating the first and second antenna structures relative to the first and second outer surfaces. In case of separate arms, customized orientations of the first and second antenna structures are enabled. Moreover, it should be noted that the second antenna or antenna structure and a pusher pushing the device under test into the device under test socket may be in a fixed positional relationship. Accordingly, the relative position between the device under test and the second antenna or antenna structure may be very accurate and well-repeatable, which improves testing repeatability. For example, the pusher pushing the device under test into the device under test socket may be a directly (mechanically) connected with the second antenna or antenna structure, which results in a particularly good accuracy.

According to an embodiment, the second antenna or antenna structure is part of a pusher for pushing the angled device under test into the device under test socket, or the second antenna or antenna structure is configured to be moveable together with a pusher for pushing the angled device under test into the device under test socket (wherein, for example, the pusher is arranged such that the pusher, or a part of the pusher, is in between the second antenna or antenna structure and the second outer surface of the angled device under test when the device under test in inserted into the device under test socket) (and wherein, for example, the pusher is arranged such that the pusher, or a part of the pusher, is in between the first antenna or antenna structure and the first outer surface of the angled device under test when the angled device under test is inserted into the device under test socket).

Accordingly, the second antenna or antenna structure is movable with the pusher and can therefore be moved (e.g., for easier coupling of the angled device under test to the device-under-test socket) or readjusted (e.g., an orientation thereof). Since the pusher is configured to push the angled device under test into the device-under-test socket, the pusher facilitates coupling and positioning the second antenna or antenna structure during coupling of the angled device under test to the device-under-test socket. A good positional accuracy can be achieved using such an arrangement. Moreover, mechanical conflicts between the pusher and the second antenna or antenna structure can be reliably avoided.

According to an embodiment, the second antenna or antenna structure is configured to be connected with a signal source and/or with a signal receiver via a blind-mating microwave connection (e.g. via a blind mating (hollow) waveguide connection) when the handler has placed the second antenna or antenna structure in an operating position (or, equivalently, when the handler has inserted the angled device under test into the test socket, or when the handler pushes the device under test into the test socket).

The signal source enables the second antenna or antenna structure to emit a signal (e.g., to be received by an antenna array of the angled device under test) and/or the signal receiver allows to evaluate a received signal (e.g., emitted by an antenna or antenna array of the angled device under test and received by the second antenna or antenna structure), and therefore both the signal source and the signal receiver facilitate testing of the angled device under test. The blind-mating microwave connection may facilitate (e.g., manual and/or automatic) coupling between the signal source and/or the signal receiver and the second antenna or antenna structure. Accordingly, an efficient test is possible, even in configurations in which the second antenna or antenna structure is moveable (as outlined above).

According to an embodiment, the device under test socket comprises an angled recess or an angled exemption, configured to support and/or align the angled device under test. The angled recess or an angled exemption may have a sidewall on one or both of its ends.

The angled recess or an angled exemption has two (or more) abutment surfaces (e.g., at an angle) that can abut against the first and second outer surface of the device under test respectively. Such abutment surfaces may realize (at least partly) a pre-determined orientation and/or position of the angled device under test. A pre-determined orientation and/or position of the angled device under test may facilitate establishing an electrical connection and improve reproducibility and accuracy of testing. The optional one or more sidewalls may further limit lateral movement of the angled device under test, while typically allowing for a well-guided smooth insertion of the device under test into the device under test socket.

According to an embodiment, the device under test socket comprises one or more coaxial pogo pins (which may, for example, extend from a lower surface of the device under test socket which is in contact with the PCB test fixture or load board, to an upper surface of the device under test socket, which is in contact with the second inner surface of the angled device under test), in order to establish an electrical connection between the PCB test fixture or loadboard and the angled device under test (wherein, for example, a first end of the coaxial pogo pin may be in contact with a pad on the PCB test fixture or load board, and wherein, for example, a second end of the coaxial pogo pin may be in contact with a pad on the angled device under test or with a connector of the angled device under test).

Pogo pins are commonly depressible and allow the device-under-test socket to establish a reliable electrical contact with the device under test upon the device under test being coupled to the device-under-test socket (e.g., when being pushed by a handler/pusher into the device-under-test socket). For example, the coaxial springs (or spring-loaded pins) enable a high frequency interconnect to the device-under-test socket.

According to an embodiment, the test arrangement comprises at least two device under test sockets configured to carry respective angled devices under test (e.g. two equal devices under test), wherein the at least two device under test sockets are arranged (e.g. back-to-back) to position respective angled devices under test such that respective first outer surfaces of the respective angled devices under test are aligned in opposite (averted) directions.

A test arrangement with at least two device-under-test sockets allows testing more than one device under test at once (e.g., simultaneously or successively; e.g. within one cycle of a handler placing the devices under test in the device under test sockets). Furthermore, with the respective first outer surfaces of the respective angled devices under test being aligned in opposite (averted) directions, interferences between signals emitted by and/or received at the respective first outer surfaces are reduced.

According to an embodiment, the test arrangement comprises at least two rows (e.g. parallel rows) of device under test sockets, wherein the device under test sockets are configured to carry respective angled devices under test, wherein the at least two rows of device under test sockets are arranged (e.g. back-to-back; e.g. with sides of the device under test sockets where the first outer surfaces of the devices under test are located, averted with respect to each other) to position respective angled devices under test such that respective first outer surfaces of the respective angled devices under test are aligned in opposite (averted) directions.

Such an arrangement improves a compromise between arranging a plurality of devices under test in an increased density and reducing interferences between signals emitted by and/or received at the respective first outer surfaces.

According to an embodiment, the carrier structure comprises at least two openings, with a solid intermediate portion (e.g. a solid bar) in between, wherein the two or more device under test sockets are arranged on the solid intermediate portion between the openings, and wherein device under test positions of one or more of the device under test sockets are aligned towards a first opening of the at least two openings, and wherein device under test positions of one or more of the device under test sockets are aligned towards a second opening of the at least two openings (such that devices under test inserted into two device under test sockets on the solid intermediate portion that are arranged back-to-back are aligned towards different openings).

Such an arrangement improves a compromise between arranging a plurality of devices under test in an increased density and reducing interferences between signals emitted by and/or received at the respective first outer surfaces. Furthermore, the first and/or second opening can form a common opening for a plurality of devices under test, which may cause less interferences than a plurality of openings for each device under test. In other words, an opening may be extended, such that it is associated with a plurality of devices under test. Thus, lobes of antennas or antenna structures of a plurality of devices under test may reach into a common opening. However, If side lobe levels of adjacent devices under test sharing a common opening are sufficiently low, or if adjacent devices under test are tested at sufficiently different frequencies, a simultaneous testing of multiple devices under test is possible. Furthermore, the absence of conductive or dielectric materials in the (common) opening may help to reduce a crosstalk between adjacent devices under test.

An embodiment of the invention is directed at a test arrangement for over-the-air testing an angled (e.g. L-shaped) device under test (e.g. a L-shape Antenna-in-package device under test), wherein the test arrangement comprises a carrier structure (e.g. a PCB test fixture or a loadboard); wherein the test arrangement comprises a device-under-test socket which is coupled to the carrier structure (e.g. the PCB test fixture or the load board) (e.g. directly or with an extender assembly and/or a PCB interposer in between the carrier structure and the device-under-test socket), wherein the device-under-test socket is configured to establish an electrical contact with an inner surface of the angled (e.g. L-shaped) device under test (e.g. with an inner surface of the angled device under test which is opposite to a second outer surface of the angled device under test) or with a connector which is arranged on the inner surface of the angled (e.g. L-shaped) device under test, and wherein the device-under-test socket is configured to position the angled device-under-test such that a surface normal of a first outer surface of the angled (e.g. L-shaped) device-under-test is parallel, within a tolerance of +/−15 degrees, to the surface (e.g. main surface) of the loadboard, and such that a second outer surface of the angled (e.g. L-shaped) device under test (e.g. a surface comprising a radiating structure) is facing away from the loadboard, and such that a surface normal of the second outer surface of the angled (e.g. L-shaped) device-under-test is perpendicular, within a tolerance of +/−15 degrees, to the surface of the loadboard, wherein the carrier structure (e.g. the test fixture PCB or the load board) comprises an opening (e.g. a hole or a cutout) extending away from the device-under-test socket in a direction of an outward surface normal of the first outer surface of the angled device-under-test (e.g. away from the device-under test socket in a main radiation direction of an antenna structure on the first outer surface of the device-under-test).

Such a test arrangement combines may of the advantages mentioned above.

### BRIEF DESCRIPTION OF THE DRAWINGS

Embodiments of the present invention will be detailed subsequently referring to the appended drawings, in which:

FIG. 1 shows a schematic cross-section of an example of a test arrangement for over-the-air testing an angled device under test;

FIG. 2A shows a schematic cross section through a first example of an angled device under test;

FIG. 2B shows a schematic cross section through a second example of an angled device under test;

FIG. 3 shows a perspective view of an angled device under test;

FIG. 4 shows a result of a simulation of a far field emitted by an antenna element of a first antenna array of the first outer surface of the device under test depicted in FIG. 3;

FIG. 5 shows a perspective view of an angled device under test;

FIG. 6 shows a result of a simulation of a far field emitted by an antenna element of the first antenna array of the first outer surface of the device under test depicted in FIG. 5;

FIG. 7A shows a perspective view of an example of a device under test;

FIG. 7B shows a different perspective view of the device under test depicted in FIG. 7A;

FIG. 8 shows a schematic top view of an example of a test arrangement;

FIG. 9 shows a schematic cross section of an example of a test arrangement with a carrier structure, a device-under-test socket with a device under test;

FIG. 10 shows a perspective view of an example of a device-under-test socket;

FIG. 11A shows a schematic cross section of an example of a test arrangement with a carrier structure, a device-under-test socket with a device under test;

FIG. 11B shows a perspective view of the test arrangement shown in FIG. 11A;

FIG. 12 shows a schematic top view of an another example of a test arrangement with a plurality of devices under test; and

FIG. 13 shows a schematic top view of an another example of a test arrangement with a plurality of devices under test.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be optionally combined with each other, unless specifically noted otherwise.

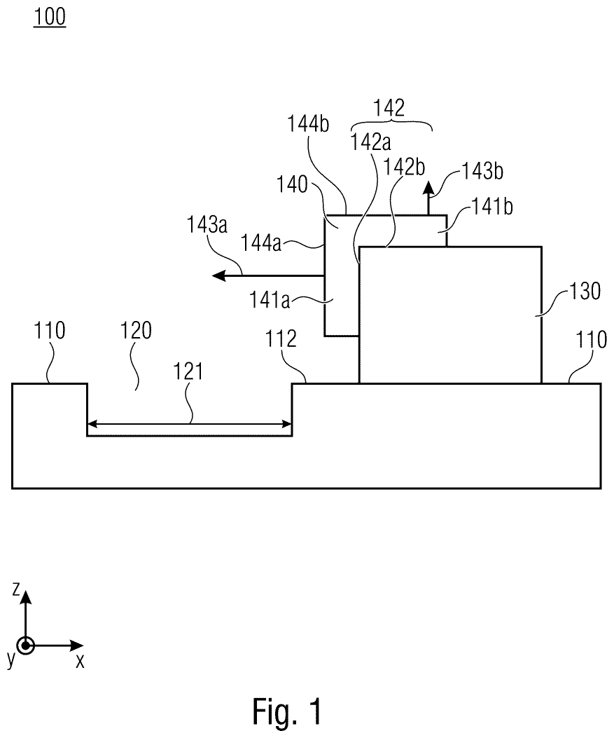

FIG. 1 shows a schematic cross-section of an example of a test arrangement 100 for over-the-air testing an angled device under test 140.

The test arrangement comprises a carrier structure 110 and a device-under-test socket 130, which is coupled to the carrier structure 110. The device-under-test socket 130 is configured to establish an electrical contact with an inner surface 142 of the angled device under test 140 or with a connector (not shown in FIG. 1) which is arranged on the inner surface 142 of the angled device under test 140. The carrier structure comprises an opening 120 extending away from the device-under-test socket 130 in a direction of an outward surface normal 143a of a first outer surface 141a of the angled device-under-test 140.

The carrier structure 110 may be (or comprise) a printed circuit board (PCB) test fixture or a loadboard. The carrier structure 110 may, for example, comprise regions with a flat surface. The device-under-test-socket 130 may be arranged on top of the carrier structure 110 (e.g., on the flat surface) or may be coupled to the carrier structure 110 via one or more intermediate devices or structures.

The test arrangement 100 shown in FIG. 1 can, for example, be used to test the angled device under test 140 itself (e.g., without antenna structures detecting electromagnetic radiation emitted by the angled device under test) or to test the angled device under test 140 in combination with one or more additional antennas. For example, the test arrangement 100 may be used to test a power consumption of the device under test 140 or interferences between antennas of the device under test 140. Alternatively, the test arrangement 100 may be configured to wirelessly test one or more antenna structures of the device under test

Since the device-under-test socket 130 is configured to contact an inner surface 142 of the device under test, outer surfaces of the device under test 140 completely (or at least mostly) face away from the device-under-test socket 130 and the carrier 110. Therefore, an effect of the device-under-test socket 130 and/or the carrier structure 110 on a radiation emitted (and/or received) by the outer surfaces of the device under test 140 (and on a testing thereof) is reduced. Also, the opening 120 reduces an impact of the carrier structure 110 onto the device under test and consequently onto a test result.

The angled device under test 140 may, for example, be (or comprise) an Antenna-in-package (AiP) device. The angled device under test 140 may, for example, have an L-shape (as indicated abstractly in FIG. 1). For example, the device under test may be a device with a first plate 141a connected to a second plate 141b, wherein the first plate 141a and the second plate 141b may, for example, be angled relative to each other at at least essentially 90 degrees (e.g., within a tolerance of +/−15 degrees). The angled device under test 140 may comprise a first outer surface 144a (e.g., of the first plate 141a) and a second outer surface 144b (e.g., of the second plate 141b), wherein, for example, the first and second outer surfaces 144a, b are angled relative to each other at at least essentially 270 degrees (e.g., within a tolerance of +/−15 degrees). The inner surface 142 of the angled device under test 140 may comprise a first inner surface 142a (e.g., of the first plate 141a) and a second inner surface 142b (e.g., of the second plate 141b), wherein, for example, the first and second inner surfaces 142a, b are angled relative to each other at at least essentially 90 degrees (e.g., within a tolerance of +/−15 degrees). The first inner surface 142a and the first outer surface 144a may, for example, be arranged parallel to each other. The second inner surface 142b and the second outer surface 144b may, for example, be arranged parallel to each other.

The device-under-test socket 130 may be configured to position the angled device-under-test 140 such that the second outer surface 144b of the angled device under test 140 is facing away from the carrier structure 110. The device-under-test socket 130 may be configured to position the angled device-under-test 140 such that a surface normal 143b of the second outer surface 144b of the angled device-under-test is perpendicular, within a tolerance of +/−15 degrees, to the surface 112 of the carrier structure 110. The second outer surface 144b may be arranged parallel to the surface 112 of the carrier structure 110.

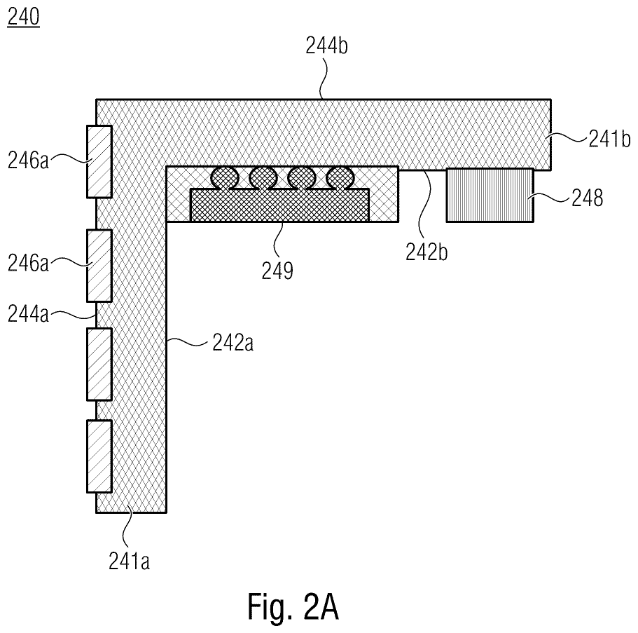

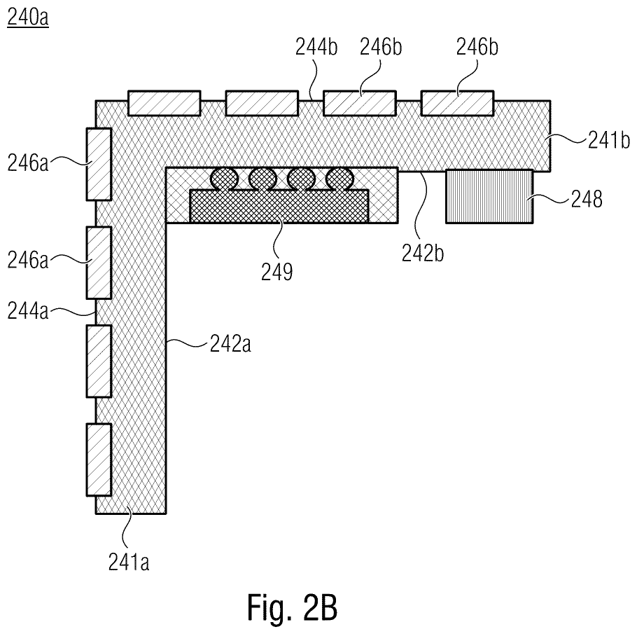

FIG. 2A shows a schematic cross section through a first example of an angled device under test 240, which can take the place of the angled device under test 140.

The device under test 240 comprises a first plate 241a and a second plate 241b, which are angled relative to each other at a 90 degree angle (e.g., within a tolerance of +/−15 degrees). The first plate 241a comprises a first outer surface 244a and a first inner surface 242a and the second plate 241b comprises a second outer surface 244b and a second inner surface 242b.

In the example shown in FIG. 2A the first outer surface 244a comprises a first antenna array 246a with four antenna elements. However, the first outer surface 244a may (additionally or alternatively) comprise any other form of antenna (e.g., a single antenna and/or a circular polarized antenna) and any other number of antenna elements or antenna arrays. Alternatively, the second outer surface 244b may comprise the first antenna array 246a. The first antenna array 246a may be configured to receive and/or transmit electromagnetic radiation.

The device under test 240 may further comprise a connector 248, e.g., an array connector. In the example shown in FIG. 2A, an (array) connector 248 is arranged on the second inner surface 242b. Alternatively, the (array) connector 248 may be arranged on the first inner surface 242a or (e.g., in the case of a plurality of (array) connectors 248) on the first and second inner surface 242a, b. The (array) connector 248 is electrically connected with at least one (e.g., all of the) antenna elements of the first antenna array 246a. Therefore, an electrical signal applied at the (array) connector 248 may cause the first antenna array 246a to emit electromagnetic radiation. Alternatively or additionally, electromagnetic radiation received by the first antenna array 246a may result in an electric signal at the (array) connector 248. The (array) connector 248 may be or comprise one or more solder balls. The (array) connector 248 may be configured to connect the device under test 140 (e.g., an antenna in package module) to a system (e.g. a cell phone or the device-under-test socket 130) and may enable transmission of signals like a power signal, a digital signal, radio frequency (RF) of intermediate frequency (IF).

The first antenna array 246a may be electrically connected directly with the (array) connector 248 or may be indirectly coupled with the (array) connector 248, e.g., with further electrical components in between. For example, the further electrical components may comprise at least one of an amplifier, a filter, a switch, a resistor, a capacitor, and an integrated circuit. In the example shown in FIG. 2A, the further electrical components comprise an antenna circuitry 249 (e.g., a silicon die). The antenna circuitry 249 may be configured to convert intermediate frequency (IF) signals into mmWave signals (e.g., of a 5G bandwidth such as in a range of 24 GHz to 53 GHZ) and/or vice versa. Alternatively or additionally, the antenna circuitry 249 may be configured to control (at least partly) beamforming of the first antenna array 246a.

FIG. 2B shows a schematic cross section through a second example of an angled device under test 240a, which can take the place of the angled device under test 140.

The second example of the angled device under test 240a essentially corresponds to the first example of the angled device under test 240 as shown in FIG. 2A, such that identical elements will be designated with identical reference numerals, but further comprises a second antenna array 246b on the second outer surface 244b. The second antenna array 246b may have similar features as the first antenna array 246a. The second antenna array 246b may also be electrically connected to at least one of the (array) connector 248 and the antenna circuitry 249. Alternatively, the second antenna array 246b may be electrically connected to a separate array connector and/or to a separate antenna circuitry.

The device-under-test socket 130 may be configured to position the angled device-under-test 140 (e.g. the angled device under test 240 or the angled device under test 240a) such that the first outer surface 144a of the angled device under test 140 (e.g., the first outer surface 244a) is spaced apart from a surface 112 of the carrier structure 110. The device-under-test socket 120 may be configured to position the angled device-under-test 140 such that that the surface normal 143a of the first outer surface 144a of the angled device-under-test 140 is parallel (as exemplarily depicted in FIG. 1), e.g., within a tolerance of +/−15 degrees, to the surface 112 of the carrier structure 110. The first outer surface 144a may be arranged perpendicular to the surface 112 of the carrier structure 110.

The device-under-test socket 120 may be configured to position the angled device-under-test 140 such that a spacing (e.g., the first distance 114) between the first outer surface 144a of the angled device under test 140 and the carrier structure 110 (e.g., the surface 112 thereof) is at least two wavelengths at a lowest frequency of operation of the angled device under test (or at least 10 mm, or of at least 30 mm, or of at least 45 mm). The angled device under test 140 may be operated in a frequency band of the 5G standard, for example within the range of 24 GHz to 53 GHZ (e.g., the frequency rage 2). In such a case, the lowest frequency of operation may be 24 GHz with a wavelength of 12.5 mm. The space between the first our surface 144a and the surface 112 of the carrier structure 110 may, for example, be 25 mm or larger (i.e. two times 12.5 mm).

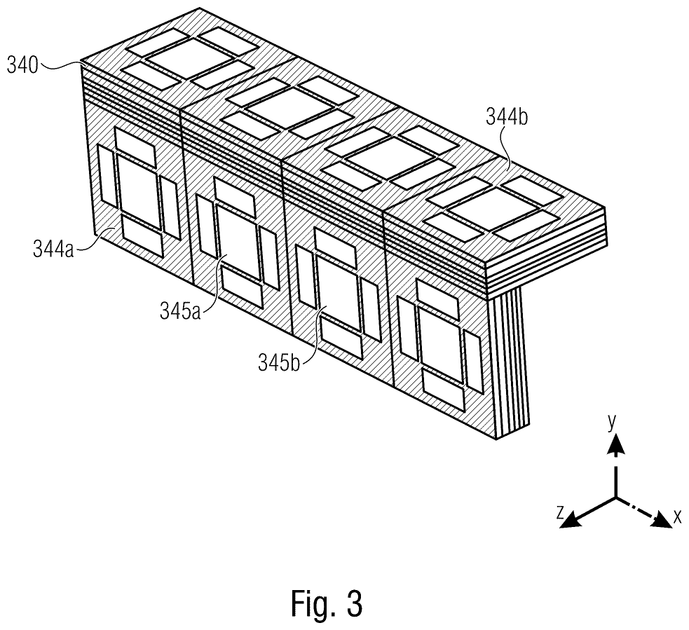

FIG. 3 shows a perspective view of an angled device under test 340, which can take the place of the angled device under test 140. The device under test 340 comprises a first outer surface 344a having a first antenna array with four antenna elements and a second outer surface 344b having a second antenna array with four antenna element. At least one antenna element may comprise at least one parasitic patch. In the example shown in FIG. 3, each antenna element has four parasitic patches surrounding a center antenna structure. The first outer surface 344 a comprises two central antenna arrays 345a, b. There is not metalized surface in the vicinity of the device under test 340.

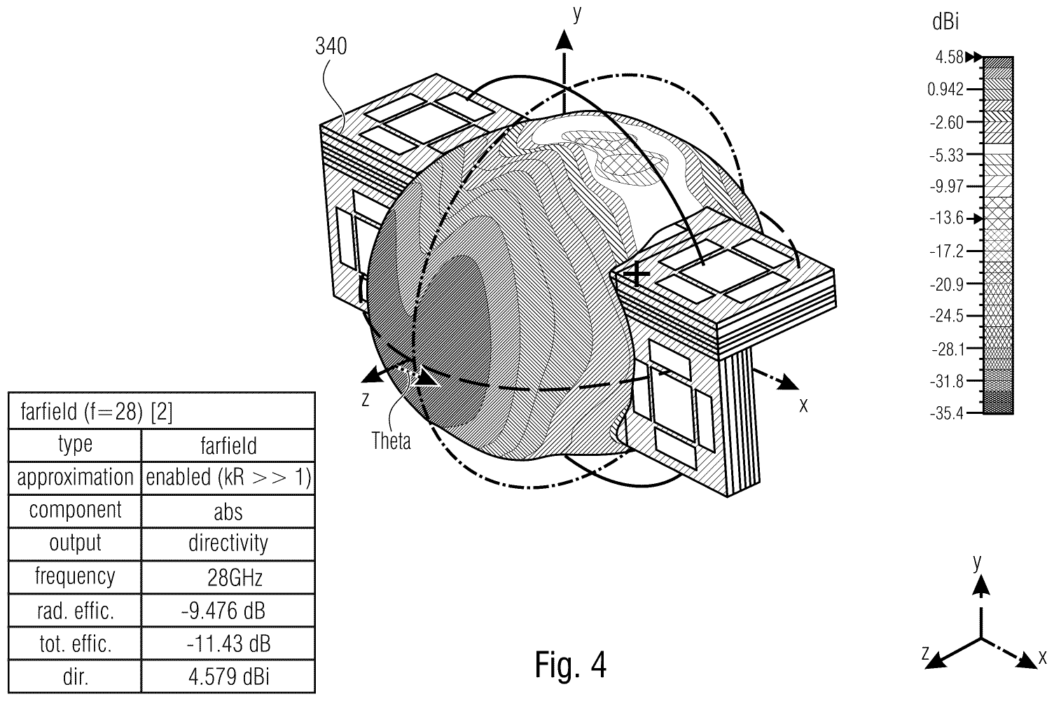

FIG. 4 shows a result of a simulation of a far field emitted by an antenna element (e.g., antenna element 345a or 345b) of the first antenna array of the first outer surface 344a of the device under test 340 depicted in FIG. 3. It is noted that for the sake of simplicity, the simulation of the far field is depicted in FIG. 3 originates from a center of the antenna array of the first outer surface 344a (e.g., between the central antenna elements 345a, b). However, the simulation of the far field may have an at least essentially identical shape when originating from a center of one of the central antenna elements 345a, b. The far field shows pronounced lobes oriented perpendicular to the two central antenna elements 345a, b of the first outer surface 344a (wherein, however, a radiation in a backward direction may be reduced or suppressed when the device under test 340 is applied in a system, e.g., in a system providing a metallized backplane).

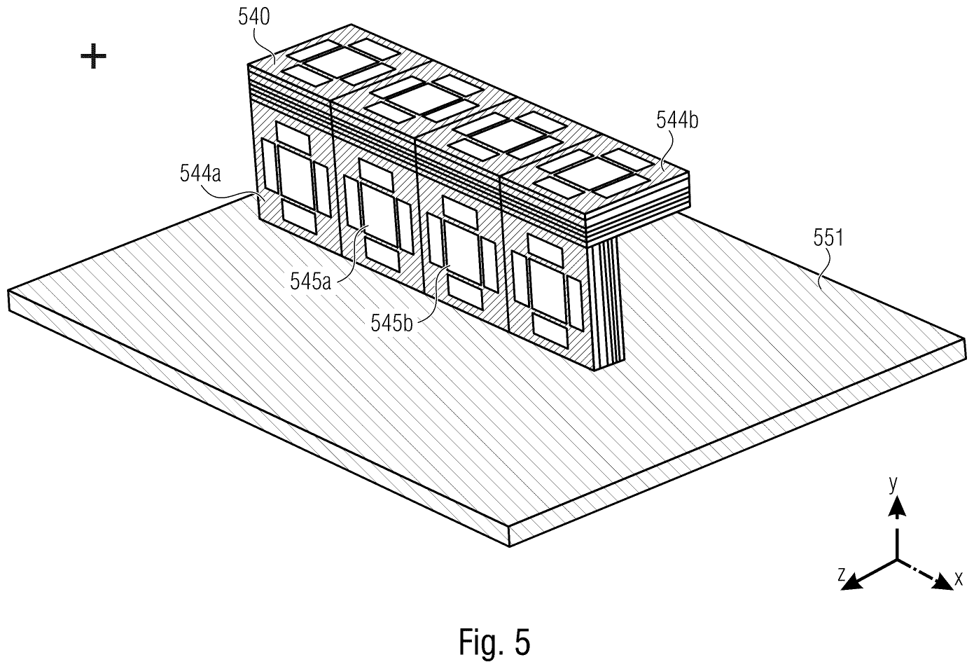

FIG. 5 shows a perspective view of an angled device under test 540, which can take the place of the angled device under test 140. The device under test 540 comprises a first outer surface 544a having a first antenna array with four antenna elements and a second outer surface 544b having a second antenna array with four antenna elements. The first antenna array of the first outer surface 544 a comprises two central antenna elements 545a, b. There is metal (e.g., copper) surface 550 in a distance of 2 mm away from the first outer surface 544a.

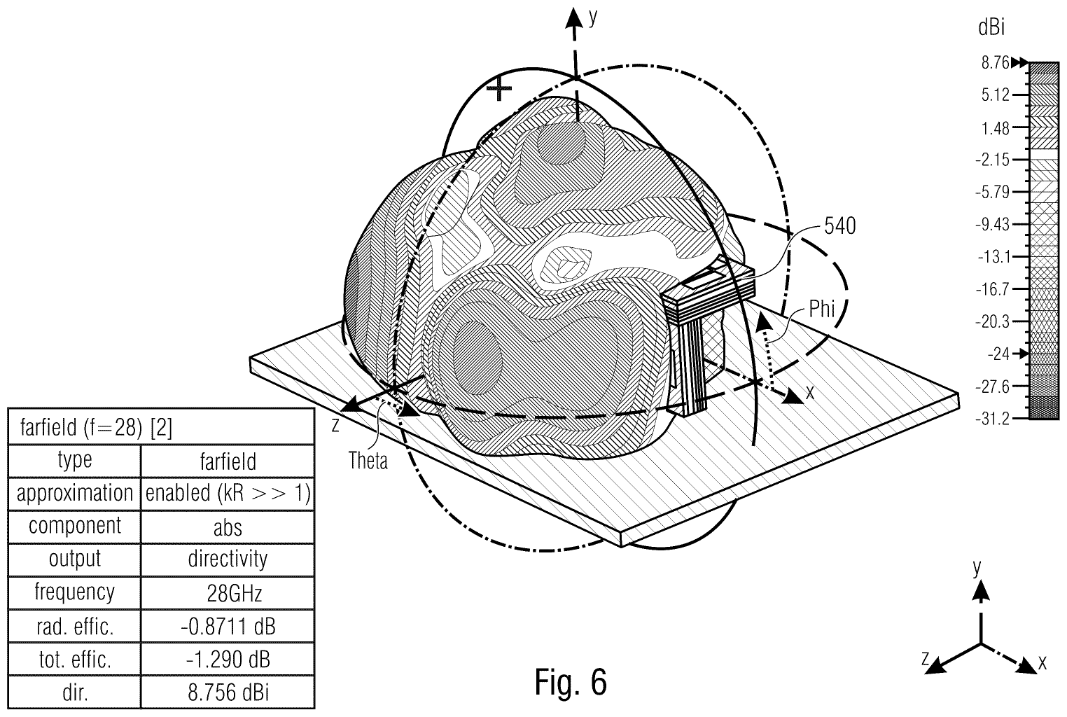

FIG. 6 shows a result of a simulation of a far field emitted by an antenna element (e.g., by antenna element 545a or 545b) of the first antenna array of the first outer surface antenna array 544a of the device under test 530 depicted in FIG. 5 (taking into consideration the metal surface 550). Compared to the result depicted in FIG. 4, the far field shows less pronounced radiation oriented perpendicular to the two central antenna elements of the first outer surface 544a. Instead, the intensity of the far field is distributed more evenly around the device under test 540, with separate mainlobes in two directions which are different from a direction of a surface normal onto the first outer surface 544a. The result shows that a metalized surface in a close vicinity can affect the far field emitted by the device under test 540 and therefore reduce the accuracy and/or reproducibility of the test. For example, a metalized surface may reduce a spatial selectivity of a beamforming antenna array and/or change the direction of the mainlobe(s).

Therefore, an opening in the carrier structure and, optionally, a spacing such as described above (e.g., at least two wavelengths, or at least 10 mm, or of at least 30 mm, or of at least 45 mm) can improve the accuracy and/or reproducibility of the test.

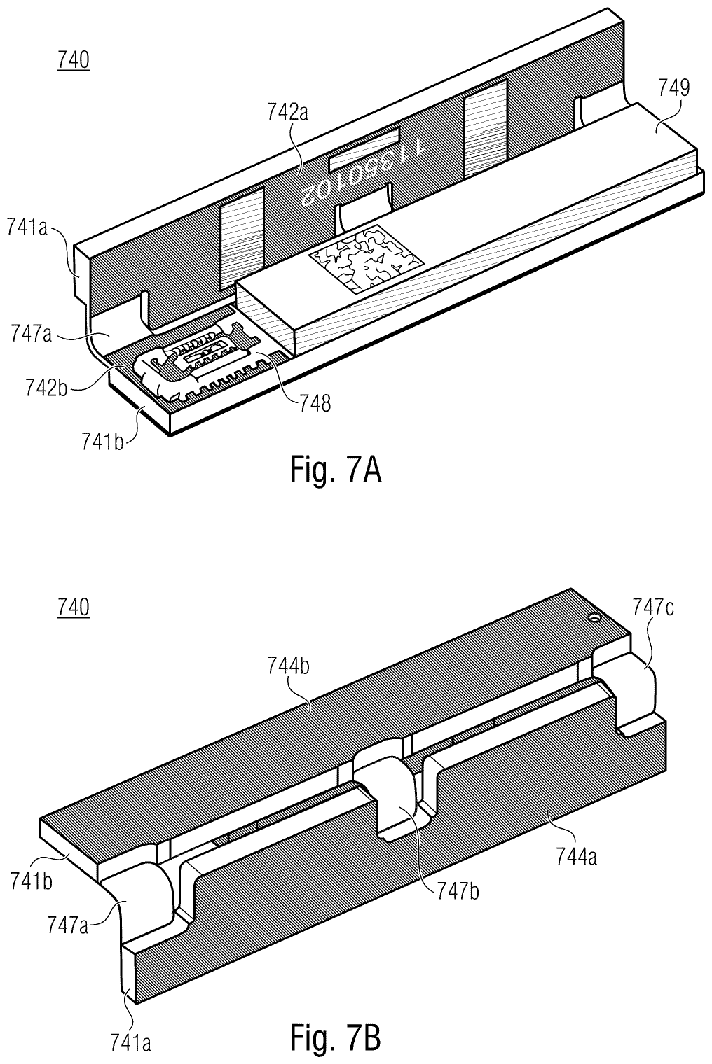

FIG. 7A shows a perspective view of an example of a device under test 740. The device under test 740 comprises a first inner surface 742a and a second inner surface 742b. In the example shown in FIG. 7A, the device under test comprises a first plate 741a having the first inner surface 742a and a second plate 741b having the second inner surface 742b. The first and second plate 741a, b are mechanically (and optionally electrically) connected by flexible conducting structures such as three flexible printed circuits 747a, b, c. The first and second plate 741a, b may be movable (e.g., rotatable or bendable) relative to each other, e.g., in order to facilitate manufacturing or assembly in a system). However, the movability of the plates may, in some cases, facilitate a coupling to the device-under-test socket, but may also complicate testing in some cases. Alternatively, the first and second plate 741a, b may be arranged fixedly relative to each other.

The device under test 740 comprises a connector or an array connector 748 and a silicon die 749 (or any other antenna circuitry) on the second inner surface 742b. The silicon die 749 may be electrically contacted indirectly via the array connector 748 or directly via electrical contacts of the silicon die 749 itself (not shown in FIG. 7A). The device-under-test socket described herein is configured to establish an electrical contact with the inner surface of the device under test 740, for example with the array connector 748 on the second inner surface 742b.

FIG. 7B shows a different perspective view of the device under test 740 depicted in FIG. 7A. The device under test 740 comprises a first outer surface 744a (on the first plate 741a) and a second outer surface 744b (on the second plate 741b). The first and second outer surfaces 744a, b (or, for example, respective antennas or antenna structures formed or arranged on the first and second outer surfaces) are configured to emit and/or receive electromagnetic radiation. To this end, antenna elements (e.g., antenna arrays) may be arranged at least partly on the first and/or second outer surfaces 744a, b or may be arranged at least partly within the first and/or second plate 741a, b. In the example shown in FIG. 7B, the first and second outer surfaces 744a, b are configured to emit and/or receive electromagnetic radiation.

Alternatively, only the first or only the second outer surface 744a, b may be configured to emit and/or receive electromagnetic radiation.

In the example shown in FIG. 1, the device-under-test socket 130 may, for example, be configured to position the angled device-under-test 140 (or, for example, the angled device under test 740, which may, for example, take the place of the angled device under test 140) such that the surface normal 143a of a first outer surface 141a of the angled (e.g. L-shaped) device-under-test (or of the first outer surface 741a) is parallel, within a tolerance of +/−15 degrees, to the surface (e.g. main surface) of the carrier structure (e.g., of the loadboard). Alternatively, the device-under-test socket 130 is be configured to position the angled device-under-test 140 (or the angled device under test 740) in any other angle.

In the example shown in FIG. 1, the device-under-test socket 130 is configured to position the angled device-under-test 140 (or the angled device under test 740) such that the second outer surface 144b of the angled (e.g. L-shaped) device under test 140 (e.g. a surface comprising a radiating structure) (or the second outer surface 744b) is facing away from the carrier structure 110 (e.g., loadboard), and such that the surface normal 143b of the second outer surface 144b of the angled (e.g. L-shaped) device-under-test 140 (or of the second outer surface 744b) is perpendicular, within a tolerance of +/−15 degrees, to the surface of the carrier structure (e.g., loadboard).

In the example shown in FIG. 1, the opening 110 forms a blind hole that does not extend through the full thickness of the carrier structure 110. A blind hole may reduce the risk of components falling through (e.g., during mounting). Alternatively, the opening 110 may be a through hole extending through a full thickness of the carrier structure 110. A through hole may reduce interferences caused by the carrier structure 110 and may facilitate guiding an electrical connections to a side of the carrier structure opposite the device-under-test socket 130 (e.g., to a signal source and/or a signal receiver).

An extension 121 of the opening in a direction of the outward surface normal 143a of the first outer surface 144a of the angled device-under-test 140 (e.g. away from the device-under test socket 130 in a main radiation direction of an antenna structure on the first outer surface of the device-under-test, in the example in FIG. 1 parallel to the x-axis, for example in a negative x direction) may be at least 2 wavelengths or at least 3 wavelengths or at least 4 wavelengths (e.g. free-space wavelengths, or wavelengths in a medium between the first outer surface of the angled device under test and the carrier structure) at a lowest frequency of operation of the angled device under test (e.g. at a lowest frequency of operation of an Antenna-in-Package (AiP) module that makes up the device under test or that is included in the device under test). For example, the angled device under test 140 may be operated in a frequency band of the 5G standard, for example in a frequency range of 24 GHz to 53 GHZ (e.g., the frequency range 2). In such a case, the lowest frequency of operation may be 24 GHz with a (free-space) wavelength of (approximately) 12.5 mm. The extension 121 of the opening in a direction of the outward surface normal 143a of the first outer surface 144a may, for example, be 25 mm or larger (i.e. two times 12.5 mm).

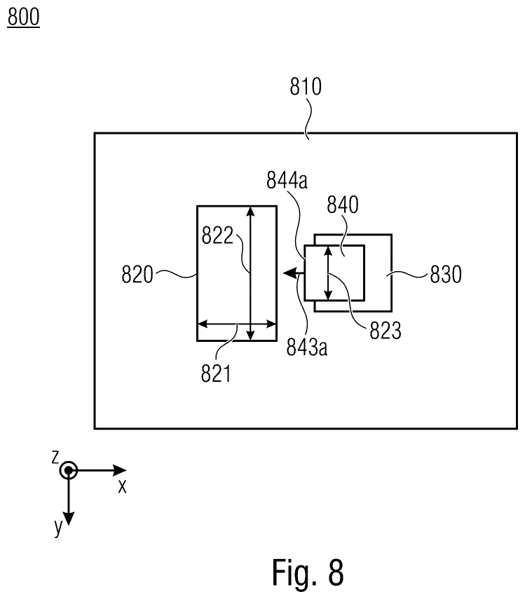

FIG. 8 shows a schematic top view of an example of a test arrangement 800. The test arrangement 100 depicted in FIG. 1 when viewed form the top may appear at least similar to the drawing in FIG. 8. In other words, any of the features, functionalities and details described with respect to the test arrangement 800 may optionally be used (or implemented) in the test arrangement 100, and vice versa.

The test arrangement 800 comprises a carrier structure 810 with an opening 820 and a device-under-test socket 830 in which a device under test 840 can be placed. The opening 820 has a rectangular shape. However, the opening 820 may have any other shape such as a circle, an oval, and a polygon. The opening 820 may comprise one or more rounded corners.

The opening comprises an extension 821 of the opening in a direction of an outward surface normal 843a of the first outer surface 844a of the angled device-under-test 840 (in FIG. 8B in the direction of the x-axis) or, equivalently, in a direction of an outward surface normal of a surface of the test socket which is configured to about to the first inner surface of the angled device under test 840. The extension 821 may, for example, be larger than two wavelengths, or larger than three wavelengths, or larger than four wavelengths, (e.g. free space wavelengths) at a lowest frequency of operation of an antenna of the device under test.

An extension 822 of the opening 820 in a direction perpendicular to the outward surface normal 843a of the first outer surface 844a of the angled device-under-test 840 (e.g. a width of the opening 820 in a direction parallel to the first outer surface 844a, for example in FIG. 8 parallel to the y-axis) is, for example, larger than an extension 823 of the device under test 840 (or, for example, larger than an extension 823 of a radiating structure on the first outer surface 844a of the device under test). The extension 822 may, for example, be larger than two wavelengths, or larger than three wavelengths, or larger than four wavelengths, (e.g. free space wavelengths) at a lowest frequency of operation of an antenna of the device under test.

Using such extensions 821,822 of the opening, it is possible to have good electromagnetic characteristics for a wireless testing of the device under test, e.g. if an antenna or an antenna structure of the device under test radiates in the direction of the surface normal 823 or if the device under test receives radiation along the direction of the surface normal 823.

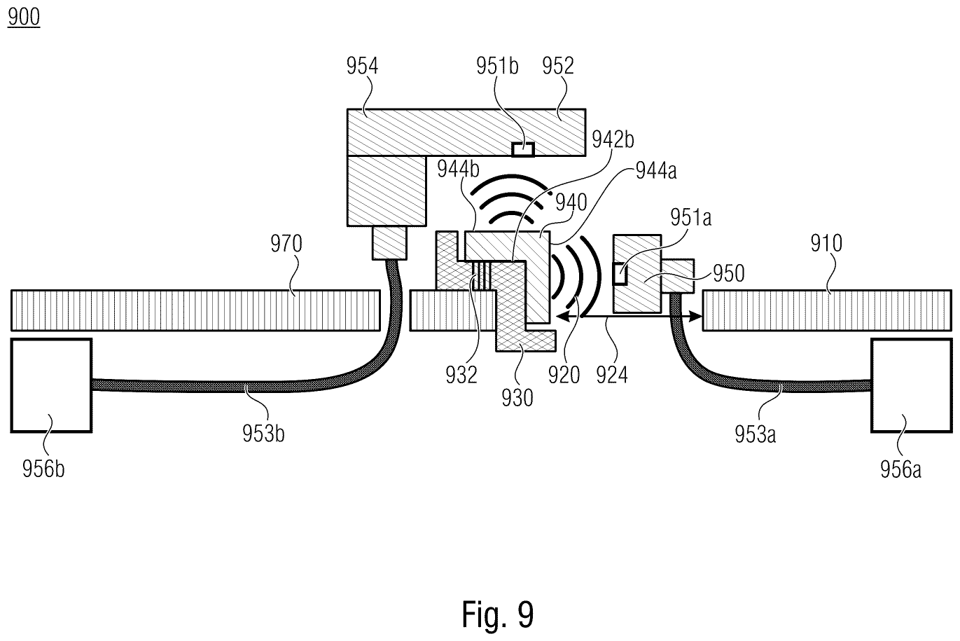

FIG. 9 shows a schematic cross section of an example of a test arrangement 900 with a carrier structure 910 and a device-under-test socket 930 which may be configured to carry a device under test 940. The carrier structure 910 comprises an opening 920 extending away from the device-under-test socket 930 in a direction of the outward surface normal 843a of a first outer surface 944a of the angled device-under-test 940 (or, equivalently, in a direction of an outward surface normal of a of first surface of the device under test socket which is adapted to about a first inner surface of the angled device under test 940). In the example shown in FIG. 9, the opening 920 is a hole extending through a full thickness of the carrier structure 910. Alternatively, the opening 930 may be a blind hole.

The device under test socket 930 is configured such that at least a portion of the device under test 940 is located in the opening 920 when the device under test 940 is inserted in the device under test socket 930. In the example shown in FIG. 9, the device-under-test socket 930 is configured such that the device under test socket 930 extends into the opening 920 (e.g., partly or entirely through the opening 920). As a result, a portion of the device-under-test 940 inserted in the device-under-test socket 930 may extend into the opening 920. Alternatively, the device-under-test socket 930 may be arranged entirely above the opening 920 (i.e. not extend into the opening 920) and the device under test 940 is dimensioned such that it extends into the opening 920 when inserted in the device-under-test socket 930. However, in other embodiments the device under test may not extend into the opening 920.

According to an embodiment, the test arrangement comprises a first antenna or antenna structure (e.g. a single aperture antenna (e.g. dual linear polarized or circular polarized)) configured to receive a signal radiated from the first outer surface of the angled device under test and/or configured to emit a signal to be received at the first outer surface of the angled device.

An extension of the opening 920 may be chosen such that a distance 924 between an edge of the angled device under test (e.g., first outer surface 944a in FIG. 9) or an edge of an antenna-in-package device and the carrier structure 910 (e.g. a distance between an edge of the angled device under test or an edge of an antenna-in-package device and a closest edge of the opening) is at least one wavelength (e.g. a free-space wavelength, or a wavelength in a medium between the first outer surface of the angled device under test and the carrier structure) at a lowest frequency of operation of the angled device under test 940 (e.g. at a lowest frequency of operation of an Antenna-in-Package (AiP) module that makes up the device under test 940 or that is included in the device under test 940) (while there is no material of the carrier structure 910 within a distance of one wavelength from the edge of the angled device under test 940 or from the edge of the antenna-in-package device).

The device under test socket 930 comprises one or more coaxial pogo pins 932, in order to establish an electrical connection between the carrier structure 910 (e.g., a PCB test fixture or loadboard of the carrier structure 910) and the angled device under test 940. The pogo pins 932 may, for example, extend from a lower surface of the device under test socket 930 (which may be in contact with a PCB test fixture or load board of the carrier structure 910) to an upper surface of the device under test socket 930 (which may be in contact with the second inner surface 942b of the angled device under test 940). For example, a first end of the coaxial pogo pin 932 may be in contact with a pad on the PCB test fixture or load board (e.g., of the carrier structure 930). A second end of the coaxial pogo pin may be in contact with a pad on the angled device under test 940 or with a connector of the angled device under test 940. The pogo pins 932 may, for example, extend beyond an upper surface of the device-under-test socket 930, wherein the pogo pins 932 are configured to shorten when the device under test 940 is inserted into the device-under-test socket 940.

In the example shown in FIG. 9, the test arrangement 900 comprises a first antenna or antenna structure 950 and a second antenna or antenna structure 952. However, the test arrangement 900 may comprise only one of the first and second antenna or antenna structures 950, 952.

The first antenna or antenna structure 950 (e.g. a single aperture antenna (e.g. dual linear polarized or circular polarized)) is configured to receive a signal radiated from the first outer surface 944a of the angled device under test 940 (or, more precisely, from an antenna or antenna structure arranged in or on the first outer surface 944a) and/or configured to emit a signal to be received at the first outer surface 944a of the angled device 940 (or, more precisely, by an antenna or antenna structure arranged in or on the first outer surface 944a). To this end, the first antenna or antenna structure 950 may be arranged at a distance from the first outer surface 944a of the angled device under test 940, such that a surface normal of the first outer surface 944a of the angled device under test 940 (or, equivalently, a surface normal of a first surface of the device under test socket which abuts a first inner surface of the device under test) extends through the aperture of the first antenna or antenna structure 950. Alternatively, the first antenna or antenna structure 940 may be arranged at a different position and/or orientation.

The first antenna or antenna structure 940 is at least partly arranged in the opening (e.g. in an open area surrounded by the carrier structure 910; e.g. in a plane of the carrier structure 910). In the example shown in FIG. 9, the first outer surface 944a and the aperture of the first antenna or antenna structure 950 are arranged such that a transmission path there between is arranged offset (in a direction perpendicular to a surface of the carrier structure 910) relative to a center plane of the carrier structure 910. Alternatively, the transmission path between the first outer surface 944a and the aperture of the first antenna or antenna structure 950 may be arranged within the center plane of the carrier structure 910.

In the example shown in FIG. 9, a radiating aperture 951a of the first antenna or antenna structure 950 is arranged outside the opening 920. Alternatively, the radiating aperture 951a of the first antenna or antenna structure 950 may be at least partly arranged in the opening 920 (e.g. in an open area surrounded by the carrier structure 910; e.g. in a plane of the carrier structure 910).

The first antenna or antenna structure 950 may be mounted to have a fixed position with respect to the device under test socket 930. Alternatively, the first antenna or antenna structure 950 may be configured to be movable relative to the device under test socket 930. A movable first antenna or antenna device 952 may increase accessibility to the device-under-test socket 930 (e.g., for inserting the device under test 940).

For example, the first antenna or antenna structure 950 may be mechanically attached to an arm of a handler, such that the first antenna or antenna structure 950 is moveable. The handler may be configured to insert the angled device under test 940 into the device under test socket 930. For example, the first antenna or antenna structure 950 may be at least partly arranged in the opening 920 when the handler pushes the angled device under test 950 into the test socket 930.

In the example shown in FIG. 9, the first antenna or antenna structure 950 comprises (or is connected to) a first coaxial cable 953a connected (or connectable) with a first signal source and/or with a first signal receiver 956a. However, any other form of electrical signal transmission (like, for example, a hollow waveguide structure) may be used instead. Alternatively or additionally, the first antenna or antenna structure 950 may be connected to any other device (which may, for example, be configured to perform or support a testing of the device under test). The first coaxial cable 953a may, for example, extend through the opening 920. Alternatively, the coaxial cable 953a may extend through an opening different from opening 920 or extend through no opening (e.g., extend at the same side of the carrier structure as the device-under-test socket 940 and/or the first antenna or antenna structure 950).

Alternatively, the first antenna or antenna structure 950 may be configured to be connected with the signal source and/or with a first signal receiver 956a via a blind-mating microwave connection (e.g. via a blind mating (hollow) waveguide connection) when the handler has placed the first antenna or antenna structure 950 in an operating position (or, equivalently, when the handler has inserted the angled device under test 940 into the test socket 930, or when the handler pushes the device under test 940 into the test socket 930).

The second antenna or antenna structure 952 (e.g. a single aperture antenna (e.g. dual linear polarized or circular polarized)) is configured to receive a signal radiated from the second outer surface 944b of the angled device under test 940 (or, more precisely, from an antenna or antenna structure arranged on or in the second outer surface) and/or to emit a signal to be received at the second outer surface 944b of the angled device under test 940 (or, more precisely, by an antenna or antenna structure arranged on or in the second outer surface) (at least when the second antenna or antenna structure 952 is placed at an operation position) (or, equivalently, when the handler has inserted the angled device under test 940 into the test socket 930, or when the handler pushes the device under test 940 into the test socket 930).

An aperture 951b of the second antenna or antenna structure 952 is arranged at a distance from a or the second outer surface 944b of the angled device under test 940 such that a surface normal of the second outer surface 944b of the angled device under test 940 extends through the aperture 951b of the second antenna or antenna structure 952 (at least when the second antenna or antenna structure 952 is placed at an operation position) (or, equivalently, when the handler has inserted the angled device under test 940 into the test socket 930, or when the handler pushes the device under test 940 into the test socket 930).

The second antenna or antenna structure 952 is mechanically attached to an arm of a handler (which may be configured to insert and/or push the angled device under test 940 into the device under test socket 930), such that the second antenna or antenna structure 952 is moveable.

It should be noted that FIG. 9 shows examples of antenna structures that can be used with and without a handler. Alternatively, none or both of the first and second antenna structures 950, 952 may be coupled/attached to a handler. The first and second antennas or antenna structures 950, 952 may be attached to the same/common handler or may each be attached to an individual handler.

The second antenna or antenna structure 952 may be coupled to a pusher for pushing the angled device under test 940 into the device under test socket 930, or the second antenna or antenna structure 952 may, for example, be configured to be moveable together with a pusher for pushing the angled device under test 940 into the device under test socket 930 (wherein, for example, the pusher is arranged such that the pusher, or a part of the pusher, is in between the second antenna or antenna structure 952 and the second outer surface 944b of the angled device under test 940 when the device under test 940 in inserted into the device under test socket 930) (and/or wherein, for example, the pusher is arranged such that the pusher, or a part of the pusher, is in between the first antenna or antenna structure 950 and the first outer surface 944a of the angled device under test 940 when the angled device under test 940 is inserted into the device under test socket 930).

The second antenna or antenna structure 952 is configured to be connected with a second signal source and/or with a second signal receiver 956b via a blind-mating microwave connection (e.g. via a blind mating (hollow) waveguide connection) when the handler has placed the second antenna or antenna structure 952 in an operating position (or, equivalently, when the handler has inserted the angled device under test 940 into the test socket 930, or when the handler pushes the device under test 940 into the test socket 930).

In the example shown in FIG. 9, the second antenna or antenna structure 952 comprises (or is connected to) a second coaxial cable 953b connected (or connectable) with the second signal source and/or with a signal receiver 956b. However, any other form of electrical signal transmission may be used instead. Alternatively or additionally, the second antenna or antenna structure 952 may be connected to any other device. The second coaxial cable 953b may extend through the opening 920. Alternatively, the second coaxial cable 953b may extend through an opening different from opening 920 (as depicted in FIG. 9) or extend through no opening (e.g., extend on the same side as the device-under-test socket 940 and/or as the first antenna or antenna structure 950).

It is noted that the test arrangement 900 shown in FIG. 9 has two separate signal sources and/or signal receivers 956a, b. However, the test arrangement 900 may have a common (e.g., single) signal source and/or signal receiver, which may be connected to the first and second antenna or antenna structure 950, 952 by separate or common electrical connections (such as a coaxial cable).

To conclude, the test arrangement according to FIG. 9 allows for an efficient testing of the device under test, wherein the partial placement of the device under test socket and of the first antenna 950 within the opening 920 helps to reduce a construction height. However, even if the device under test socket and/or the first antenna or antenna structure are not partially placed within the opening the test arrangement can still be implemented with a relatively small construction height, since the opening allows for a placement of the device under test socket and of the first antenna or antenna structure close to a plane of the carrier structure.

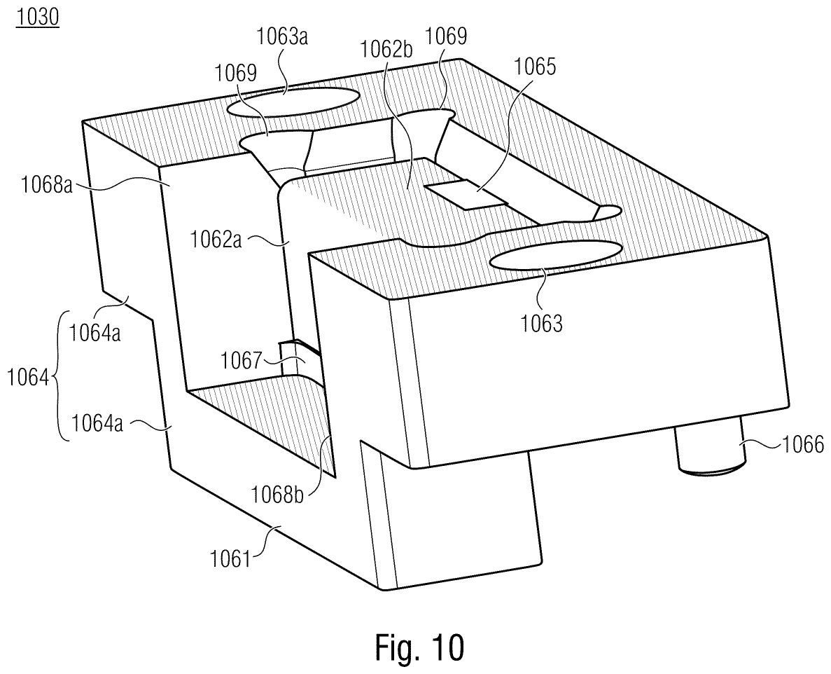

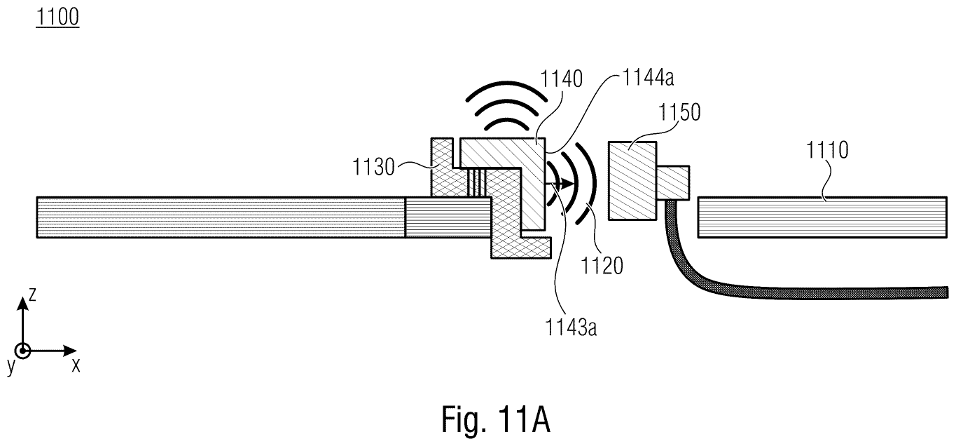

FIG. 10 shows a perspective view of an example of a device-under-test socket 1030, which may, for example, be used in any of the embodiments disclosed herein. The device-under-test socket 1030 may be configured to receive any device under test described herein and be part of any test arrangement described herein. The device-under-test socket 1030 comprises an angled recess or an angled exemption 1060, configured to support and/or align the angled device under test. The angled recess or angled exemption 1060 comprises a first abutment surface 1062a configured to abut against the first inner surface of the device under test (e.g., first inner surfaces 142a, 242a) and a second abutment surface 1062b configured to abut against the second inner surface of the device under test (e.g., second inner surface 142b, 242b, or 942b). The first abutment surface 1062a and the second abutment surface 1062b may be arranged at an abutment surface angle, wherein a sum of the abutment surface angle (e.g., 270 degrees) and of the angle between the first and second inner surface of the device under test (e.g., 90 degrees) is at least essentially 360 degrees. For example, if the first and second inner surface of the device under test may be arranged at an angle of 90 degrees, the abutment surface angle may be 270 degrees (with the sum of 90 degrees and 270 degrees being 360 degrees).

Any surface of the device-under-test socket 1030 may be configured to establish an electrical contact with the inner surface of the device under test. For example, the first and/or second abutment surface 1062a, b may be configured to establish an electrical contact with the inner surface of the device under test, and/or to provide a ground plane for an antenna structure of the device under test. To this end, the first and/or second abutment surface 1062a, b may comprise or may be formed of an electrically conducting material (e.g., at least one of gold, cupper, iron, and nickel). Alternatively, the first and/or second abutment surface may comprise, or may be formed of, a dielectric (non-conducting) material (e.g. a wear-resistant material). Optionally, the first and/or second abutment surface 1062a, b may comprise one or more (local) socket connectors 1065 (or other contacting structures for contacting the device under test, like conductive pads, pogo pins, spring-loaded contacts, or the like). The socket connector 1065 is arranged such that when the device under test is arranged in the device-under-test socket 1060, the connector 1065 establishes an electrical connection with the inner surface of the device under test or a connector thereof (e.g., array connectors 248, 748).

The device-under-test socket 1030 comprises a support body 1064 comprising a main socket structure 1064a and a leg socket structure 1064b. The main socket structure 1064a and the leg socket structure 1064b both have a rectangular cuboid outer shape (optionally with rounded edges), wherein at least two edges of the leg socket structure 1064b are smaller (shorter) than two edges (e.g., corresponding edges) of the main socket structure 1064a. The main socket structure 1064a and the leg socket structure 1064b may, for example, have the same height. A side surface 1061 of the leg socket structure 1064b is arranged flush with a side surface of the main socket structure 1064a and three other side surfaces of the leg socket structure 1064b are recessed relative to three other (corresponding) side surfaces of the main socket structure 1064a. The leg socket structure 1064b may therefore, for example, be received by an opening in the carrier structure (or other structure therebetween) such that lateral movement of the device-under-test socket 1030 is limited by side surfaces of the leg socket structure 1064b.

The device-under-test socket 1030 may further or alternatively comprise one or more protrusions 1066 extending from the support body 1064 (e.g., from the main socket structure 1064a) in a direction towards the carrier structure. The protrusion 1066 may be or comprise a shaft (e.g., with a cylinder shape). The protrusion 1066 may be received by a recess of the carrier structure (or other structure therebetween). Alternatively or additionally, the device-under-test socket 1030 may comprise one or more through holes configured to receive an attachment element such as a pin or screw.

In the example shown in FIG. 10, the angled recess or an angled exemption 1060 extends into the main socket structure 1064a and a leg socket structure 1064b. Alternatively, the angled recess or an angled exemption 1060 may only extend into the main socket structure 1064a.

The angled recess or an angled exemption 1060 may have a respective sidewall 1068a, b at both of its ends (only one of which is directly visible in FIG. 10). The sidewalls 1068a, b face each other and are arranged at least essentially parallel to each other (disregarding an optional tapering). In the example shown in FIG. 10, the sidewalls 1068a, b are oriented perpendicular or at least approximately perpendicular relative to the first and second abutment surfaces 1062a, b. The sidewalls 1068a, b may restrict lateral movement of the device under test within the angled recess or angled exemption 1060, while still allowing for a smooth and well-guided insertion of the device under test into the angled recess or the angled exemption 860 and also allowing for a smooth extraction of the device under test. Alternatively, the angled recess or angled exemption 1060 comprise only one sidewall, e.g., in order to increase flexibility in regards to positioning.

The angled recess or an angled exemption 1060 may comprise at least one tapering, e.g., such that a cross section (e.g., parallel to the first or second abutment surface 1062a, b) decreases in a direction from outside towards the first or second abutment surface 1062b. In the example shown in FIG. 10, the angled recess or angled exemption 1060 comprises a first and a second tapering. According to a first tapering a distance between the sidewalls 1068a, b decreases towards the first abutment surface 1062a. According to a second tapering, three sidewalls of the main socket structure 1064a that are surrounding the second abutment surface 1062b have a cross section that decreases towards the second abutment surface 1062b. The tapering may have a self-centering function and facilitate inserting the device under test into the angled recess or angled exemption 1060.

The device-under-test socket 1030 may have adjacent openings 1069 that intersect the angled recess or angled exemption 1060. In the example shown in FIG. 10, the device-under-test socket 1030 comprises four adjacent openings 1069 that are arranged next to corners of the second abutment surface 1062b. Alternatively, the device-under-test socket 1030 may comprise any other number of adjacent openings 1069 at any other location that is located adjacent to the second abutment surface 1062b (and/or the first abutment surface 1062a). For example, the adjacent openings may be adapted to prevent the device under test from canting, e.g. when the device under test is inserted into the socket 830. However, the adjacent openings may also be helpful to retrieve the device under test from the socket 830.

The angled recess or angled exemption 1060 may comprise additional recesses or elevations, e.g., in order to conform to a shape of the device under test. For example, the angled recess or angled exemption 1060 shown in FIG. 10 comprises a step 1067 in the first abutment surface 1062a. The step 1067 may, for example, accommodate to a structural feature of the first inner surface or provide a support surface for the device under test such as to form a space below (e.g., for grabbing the device under test).

The device-under-test socket 1030 may comprise a blind mating interface. In the example shown in FIG. 10, the main socket structure 1064a comprises two (e.g., blind) mating recesses 1061a, b. Alternatively, the main socket structure 1064a may comprise any other amount of mating recesses. The mating recesses 1061a, b are configured to receive (e.g., blind) mating protrusions of a pusher or handler (e.g., handler 754). Alternatively or additionally the main socket structure 1064a may comprise one or more (e.g., blind) mating protrusions, for example, configured to be received by a (e.g., blind) mating recess of the pusher or handler (e.g., handler 754).

To conclude, the socket 1030 may receive an angled device under test and may establish an electrical contact with the angled device under test. The device under test may be positioned (aligned) within the angled recess or angled exemption 1060, such that an over-the-air test of the device under test is possible using antenna structures or antennas on both outer surfaces of the angled device under test. The device under test is well aligned in the socket, which facilitates positioning the device under test in a compact arrangement. Furthermore, distortions of radiation characteristics of the antennas or antenna structures of the device under test by the socket may be kept reasonably small. The socket can be easily attached to a carrier structure and can be used in any of the embodiments disclosed herein.

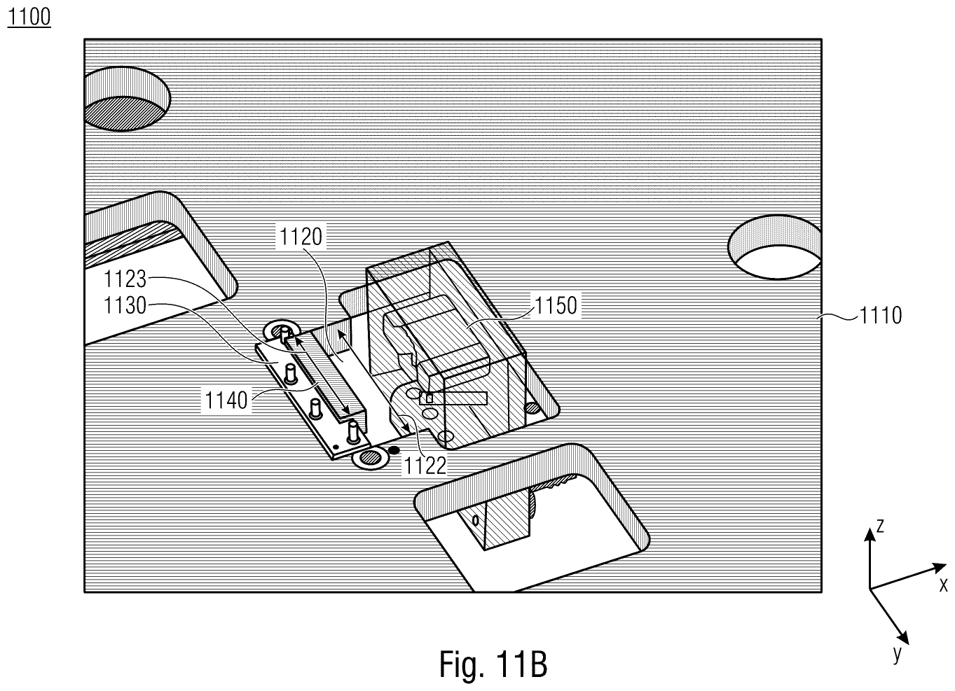

FIG. 11A shows a schematic cross section of an example of a test arrangement 1100 with a carrier structure 1110 (e.g., a printed circuit board test fixture or loadboard), a device-under-test socket 1130 with a device under test 1140 (e.g., an L-shaped device under test). The carrier structure 1110 comprises an opening 1120 extending away from the device-under-test socket 1030 in a direction of an outward surface normal 1143a of a first outer surface 1144a of the angled device-under-test 1140 (or equivalently, in a direction of an outward surface normal of a first surface of the device under test socket which abuts a first inner surface of the device under test). The test arrangement 1100 comprises a first antenna or antenna structure 1150 configured to receive a signal radiated from the first outer surface 1144a of the angled device under test 1140 (or, more precisely, from an antenna or antenna structure arranged on or in the first outer surface 1144a) and/or configured to emit a signal to be received at the first outer surface 1144a of the angled device 1140 (or, more precisely, by an antenna or antenna structure arranged on or in the first outer surface 1144a). The device under test socket 1130 is configured such that the device under test socket 1130 extends into the opening 1120.

FIG. 11B shows a perspective view of the test arrangement 1100 shown in FIG. 11A. The first antenna or antenna structure 1150 is partly arranged in the opening 1120 (wherein one or more electrical connections of the first antenna or antenna structure are, for example, arranged below the carrier structure 1110).

An extension 1122 (e.g. a width) of the opening 1120 in a direction perpendicular to an outward surface normal 1143a of the first outer surface 1144a of the angled device-under-test 1140 (or, equivalently, perpendicular to an outward surface normal of the device under test socket which abuts a first inner surface of the device under test) is larger than an extension 1123 of the device under test 1140 (e.g. in a same direction).

The opening 1120 has larger dimensions at a side opposite the device-under-test socket 1130 (or in other words: at a section surrounding the first antenna or antenna structure 1150). Therefore, the opening 1120 provides sufficient space for the first antenna or antenna structure 1150. In particular, the opening 1120 has a rectangular base shape (optionally with rounded corners) with a wider section at the side opposite the device-under-test socket 1130. For example, the opening widens (e.g. in a step wise manner) in a direction from the device under test socket towards the first antenna or antenna structure.

As can be seen in the example shown in FIG. 11B, the carrier structure 1110 may comprise further openings in addition to the opening 1120.

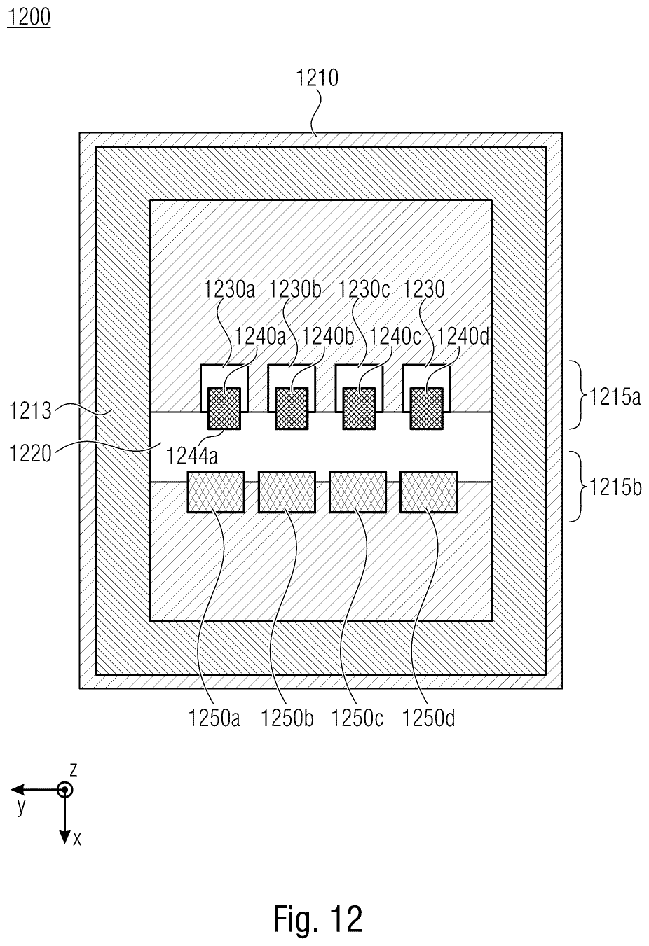

FIG. 12 shows a schematic top view of an another example of a test arrangement 1200 with a plurality of devices under test 1240a, b, c, d. The test arrangement 1200 comprises a carrier structure 1210 (which may comprise any carrier structure described herein) (e.g., a printed circuit board test fixture or loadboard) and four (e.g. four equal of different) device-under-test sockets 1230a, b, c, d (which may be any device-under-test socket described herein). However, the test arrangement 1200 may comprise any other amount of device-under-test sockets (e.g., two, three, five, six, or more).

The carrier structure 1210 comprises an opening 1220 extending away from the device-under-test sockets 1230a-d in a direction of an outward surface normal of a first outer surfaces of the angled devices under test 1240 (or, equivalently, in a direction of an outward surface normal of a first surface of the device under test socket which abuts a first inner surface of the device under test). Therefore, a plurality of devices 1240a-d share a common opening. A common opening may reduce interferences caused by the carrier structure 1210 (e.g., compared to a plurality of openings with respective borders that may cause interferences) and may also reduce a crosstalk between different devices under test.

The device under test sockets 1230 are arranged along an edge of the opening 1220. The device under test sockets 1230 may be arranged so as to be spaced apart from the opening 1220, so as to be arranged flush with opening 1220, or so as to overlap with the opening 1220 (e.g., when viewed from the top).

The plurality of devices under test 1240a-d may be arranged in a row 1215a, as depicted in FIG. 12. Moreover, a row 1215b of respective first antennas 1250a to 1250 d may be arranged opposite to the devices under test (and facing respective devices under test). The test arrangement 1200 allows testing a plurality of devices under test 1240a-d and therefore may improve test efficiency. Testing may be performed simultaneously, e.g., in order to increase time efficiency. Alternatively, testing may be performed in succession in order to reduce crosstalk between the devices under test 1240a-d.

The device-under-test sockets 1230a-d are arranged to position respective angled devices under test 1240a-d such that respective first outer surfaces (in FIG. 12, a first outer surface 1244a of a first device under test 1240a is shown as an example) of the respective angled devices under test 1240a to 1240d are aligned in the same direction (for example, in FIG. 12 in positive x-direction). The alignment in the same direction allows for a densely packed arrangement of the device-under-test sockets 1230a-d while keeping crosstalk between adjacent devices under test reasonably small.

The test arrangement 1200 comprises four first antenna or antenna structures 1250a, b, c, d (which may be any first antenna or antenna structure described herein) (e.g., side measurement antennas). However, the test arrangement 1200 may comprise any other number of first antenna or antenna structures 1250a-d, e.g., the same number as device-under-test sockets 1230a-d. In the example shown in FIG. 12, each one of the device-under-test sockets 1230a-d is assigned to a respective one of the first antenna or antenna structures 1250a-d (or vice versa). Each one of the first antenna or antenna structures 1250a-d is configured to receive a signal radiated from the first outer surface of the assigned angled device under test 1240a-d (or, more precisely, from an antenna or antenna structure arranged on or in the respective first outer surface) and/or configured to emit a signal to be received at the first outer surface of the assigned angled device under test 1240a-d (or, more precisely, by an antenna or antenna structure arranged on or in the respective first outer surface).

An aperture of at least one of the first antennas or antenna structures 1250a-d may be arranged at a distance from the respective one of the first outer surfaces of the angled devices under test 1240a-d, such that a surface normal of the first outer surface of the respective angled device under test 1240a-d (or, equivalently, a surface normal of a first surface of a respective device under test socket which abuts a first inner surface of a respective device under test) extends through the aperture of the respective one of the first antennas or antenna structures 1250a-d.

In the example shown in FIG. 12, the test arrangement 1200 does not comprise second antennas or antenna structures for the sake of not obscuring the devices under test 1240a-d. However, the test arrangement 1200 may comprise only first antennas or antenna structures (i.e. without second antennas or antenna structures), only second antennas or antenna structures (i.e. without first antennas or antenna structures), or first and second antennas or antenna structures.

The carrier structure 1210 may define a board limit 1213 (e.g., a handler docking plate limit), which defines a region (e.g., a rectangular frame) that encloses a region that supports mounting device-under-test sockets 1230a-d.

To conclude, by having a common opening for multiple device under test sockets, the test arrangement 1200 supports an efficient testing (e.g. simultaneous testing) of multiple angled devices under test, wherein a small construction height can be achieved and crosstalk between different devices under test can be kept reasonably low. The presence of an opening in the carrier structure facilitates to reach these targets.

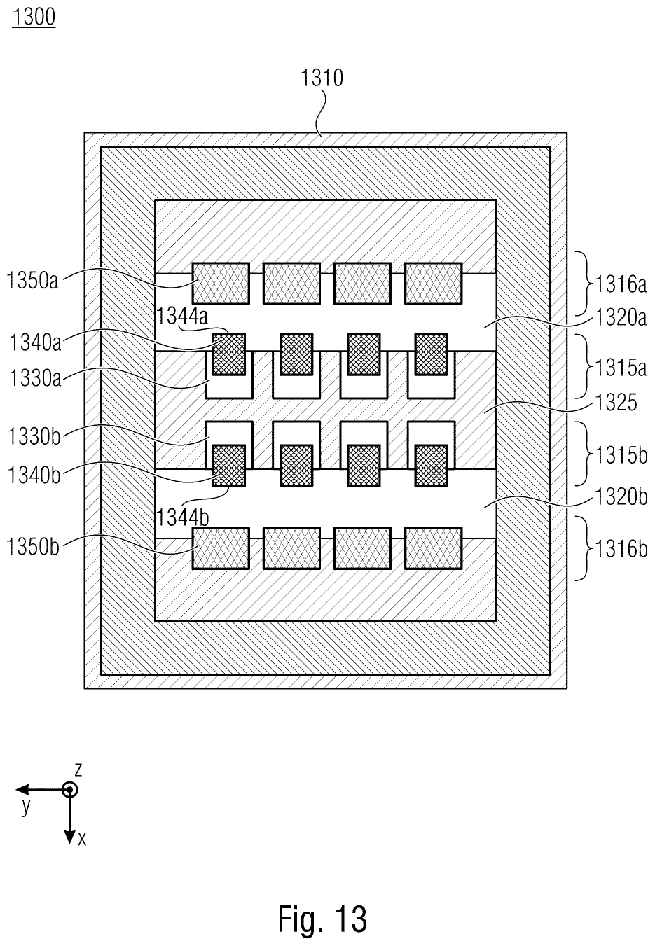

FIG. 13 shows a schematic top view of an another example of a test arrangement 1300 with a plurality of devices under test 1340. The test arrangement 1300 comprises a carrier structure 1310 (which may comprise any carrier structure described herein) (e.g., a printed circuit board test fixture or loadboard) and eight (e.g. eight equal) device-under-test sockets 1330 (which may be any device-under-test socket described herein). However, the test arrangement 1300 may comprise any other amount of device-under-test sockets (e.g., two, three, five, six, or more).

At least two device-under-test sockets 1330 are arranged (e.g. back-to-back) to position respective angled devices under test 1340 such that respective first outer surfaces 1344a of the respective angled devices under test are aligned in opposite (averted) directions (or equivalently, are arranged such that respective first surfaces of two adjacent device under test sockets that abut respective first inner surfaces of the respective devices under test are aligned in opposite directions).

For the sake of visibility, in FIG. 13 only the left most device-under-test sockets 1330 are discussed and therefore provided with reference signs 1330a, b. But the same principle applies to the remaining device-under-test sockets 1330. A first device-under-test socket 1330a is configured to arrange a respective device under test 1340 such that its respective first outer surface 1344a faces in a first direction (e.g., in FIG. 13 in a negative x-direction). A second device-under-test socket 1330b is configured to arrange a respective device under test 1340 such that its respective first outer surface 1344a faces in a second direction (e.g., in FIG. 13 in a positive x-direction) that is opposite (e.g., anti-parallel) to the first direction. As a result, the respective first outer surfaces 1344a, 1344b of the devices under test 1340a, 1340b arranged in the first and second device-under-test sockets 1330a, b face opposite directions. Consequently, first antennas or antenna structures 1350a, 1350b assigned to the respective first and second device-under-test sockets 1330a, b may be arranged at opposite orientations (e.g. in separate openings of the carrier structure). Furthermore, the first antennas or antenna structures 1350a, 1350b assigned to the respective first and second device-under-test sockets 1330a, b may be arranged such that the first and second device-under-test sockets 1330a, b are arranged between (e.g., sandwiched at a distance between) the assigned first antenna or antenna structures 1350a, 1350b. Such an arrangement reduces a risk of cross talk between devices under test 1340a, 1340b coupled to the first and second device-under-test sockets 1330a, b.

The test arrangement 1300 comprises two rows (e.g. parallel rows) 1315a, b of device-under-test sockets 1330, wherein the device-under-test sockets 1330 are configured to carry respective angled devices under test 1340, wherein the at least two rows 1315a, b of device-under-test sockets 1340 are arranged (e.g. back-to-back; e.g. with sides of the device-under-test sockets 1330 where the first outer surfaces 1344a of the devices under test 1340 are located, averted with respect to each other) to position respective angled devices under test 1340 such that respective first outer surfaces 1344a of the respective angled devices under test 1340 are aligned in opposite (averted) directions. Moreover, there are two rows 1316a, 1316b of first antennas, wherein the two rows 1315a, 1315b are arranged in between the two rows 1316a, 1316b of first antennas or first antenna structures. For example, a first (common) opening 1320a is arranged in a region between the first row 1315a of device under test sockets and the first row 1316a of first antennas, and a second (common) opening 1320b is arranged in a region between the second row 1315b of device under test sockets and the second row 1316b of first antennas. Such an arrangement improves a compromise between reduction of crosstalk and increase of packing density.

The carrier structure 1310 comprises two openings 1320a, b, with a solid intermediate portion 1325 (e.g. a solid bar) in between, wherein the for example eight device under test sockets 1330 are arranged on the solid intermediate portion 1325 between the openings 1320a, b. Device under test positions of, for example, four of the device under test sockets 1330 are aligned towards a first opening 1320a of the two openings 1320a, b. Device under test positions of other, for example, four of the device under test sockets 1330 are aligned towards a second opening 1320b of the two openings 1320a, b. In the example shown in FIG. 13, devices under test 1340 inserted into the device under test sockets 1330 on the solid intermediate portion 1325 that are arranged back-to-back are aligned towards different openings 1320a, b.

For example, at least two distances between device-under-test sockets 1330 may be at least essentially identical. For example the distance may be equal for all device-under-test sockets 1330 (e.g., a socket to socket pitch may be regular). As a result, inserting the devices under test 1340 is facilitated. The insertion may involve rotation of devices under test by 180° before insertion.

To conclude, by having two parallel of openings the test arrangement 1300 is well-suited for reaching a high testing efficiency, since many devices under test can be tested simultaneously with low cross-talk in a structure with small construction height.

### Implementation Alternatives

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A test arrangement for over-the-air testing an angled device under test, the test arrangement comprising:
a carrier structure, and
a device-under-test socket which is coupled to the carrier structure,
wherein the device-under-test socket is configured to establish an electrical contact with an inner surface of the angled device under test or with a connector which is arranged on the inner surface of the angled device under test, and
wherein the carrier structure comprises an opening extending away from the device-under-test socket in a direction of an outward surface normal of a first outer surface of the angled device-under-test.

2. The test arrangement according to claim 1,
wherein the device-under-test socket is configured to position the angled device-under-test
such that a surface normal of the first outer surface of the angled device-under-test is parallel, within a tolerance of +/−15 degrees, to the surface of the carrier structure.

3. The test arrangement according to claim 1,
wherein the device-under-test socket is configured to position the angled device-under-test
such that a second outer surface of the angled device under test is facing away from the carrier structure, and
such that a surface normal of the second outer surface of the angled device-under-test is perpendicular, within a tolerance of +/−15 degrees, to the surface of the carrier structure.

4. The test arrangement according to claim 1,
wherein the opening is a hole extending through a full thickness of the carrier structure.

5. The test arrangement according to claim 1,
wherein an extension of the opening in the direction of the outward surface normal of the first outer surface of the angled device-under-test is at least 2 wavelengths at a lowest frequency of operation of the angled device under test.

6. The test arrangement according to claim 1,
wherein an extension of the opening in a direction perpendicular to the outward surface normal of the first outer surface of the angled device-under-test is larger than an extension of a radiating structure on the first outer surface of the device under test, or
wherein an extension of the opening in a direction perpendicular to the outward surface normal of the first outer surface of the angled device-under-test is larger than an extension of the device under test.

7. The test arrangement according to claim 1,
wherein an extension of the opening is chosen such that a distance between an edge of the angled device under test or an edge of an antenna-in-package device which is part of the angled device under test and the carrier structure is at least one wavelength at a lowest frequency of operation of the angled device under test.

8. The test arrangement according to claim 1,
wherein the device under test socket is configured such that at least a portion of the device under test is located in the opening when the device under test is inserted in the device under test socket, or
wherein the device under test socket is configured such that the device under test socket extends into the opening.

9. The test arrangement according to claim 2, further comprising:
a first antenna structure;
wherein the first antenna structure is configured to receive a signal radiated from the first outer surface of the angled device under test and/or to emit a signal to be received at the first outer surface of the angled device; and
wherein an aperture of the first antenna structure is arranged at a distance from the first outer surface of the angled device under test, such that a surface normal of the first outer surface of the angled device under test extends through the aperture of the first antenna or antenna structure.

10. The test arrangement according to claim 2, further comprising:
a first antenna structure;
wherein the first antenna structure is configured to receive a signal radiated from the first outer surface of the angled device under test and/or to emit a signal to be received at the first outer surface of the angled device;
wherein the first antenna structure is at least partly arranged in the opening, or
wherein a radiating aperture of the first antenna structure is at least partly arranged in the opening.

11. The test arrangement according to claim 2, further comprising:
a first antenna structure, and
a handler;
wherein the first antenna structure is configured to receive a signal radiated from the first outer surface of the angled device under test and/or to emit a signal to be received at the first outer surface of the angled device;
wherein the first antenna structure is mechanically attached to an arm of the handler, such that the first r antenna structure is moveable.

12. The test arrangement according to claim 2, further comprising:
a first antenna structure,
a handler, and
a signal source or a signal receiver;
wherein the first antenna structure is configured to receive a signal radiated from the first outer surface of the angled device under test and/or to emit a signal to be received at the first outer surface of the angled device;
wherein the first antenna structure is connected with the signal source or with the signal receiver via a blind-mating microwave connection when the handler has placed the first antenna structure in an operating position.

13. The test arrangement according to claim 3, further comprising:
a second antenna structure;
wherein the second antenna structure is configured to receive a signal radiated from the second outer surface of the angled device under test and/or to emit a signal to be received at the second outer surface of the angled device under test;
wherein an aperture of the second antenna structure is arranged at a distance from the second outer surface of the angled device under test such that a surface normal of the second outer surface of the angled device under test extends through the aperture of the second antenna structure.

14. The test arrangement according to claim 3, further comprising:
a second antenna structure, and
a handler;
wherein the second antenna structure is configured to receive a signal radiated from the second outer surface of the angled device under test and/or to emit a signal to be received at the second outer surface of the angled device under test;
wherein the second antenna structure is mechanically attached to an arm of the handler, such that the second antenna or antenna structure is moveable.

15. Test arrangement according to claim 13, further comprising:
a pusher;
wherein the pusher is configured to push the angled device under test into the device under test socket;
wherein the second antenna structure is part of the pusher, or
wherein the second antenna structure is configured to be moveable together with the pusher.

16. Test arrangement according to claim 1,
wherein the device under test socket comprises an angled recess or an angled exemption, configured to support and/or align the angled device under test; and
wherein the device under test socket comprises one or more coaxial pogo pins, in order to establish an electrical connection between a PCB test fixture or a load board and the angled device under test.

17. The test arrangement according to claim 1,
wherein the test arrangement comprises at least two device under test sockets configured to carry respective angled devices under test,
wherein the at least two device under test sockets are arranged to position respective angled devices under test such that respective first outer surfaces of the respective angled devices under test are aligned in opposite directions.

18. The test arrangement according to claim 1,
wherein the test arrangement comprises at least two rows of device under test sockets,
wherein the device under test sockets are configured to carry respective angled devices under test,
wherein the at least two rows of device under test sockets are arranged to position respective angled devices under test such that respective first outer surfaces of the respective angled devices under test are aligned in opposite directions.

19. The test arrangement according to claim 1,
wherein the carrier structure comprises at least two openings, with a solid intermediate portion in between,
wherein two or more device under test sockets are arranged on the solid intermediate portion between the openings, and
wherein device under test positions of one or more of the device under test sockets are aligned towards a first opening of the at least two openings, and wherein device under test positions of one or more of the device under test sockets are aligned towards a second opening of the at least two openings.

20. A test arrangement for over-the-air testing an angled device under test, the test arrangement comprising:
a carrier structure, and
a device-under-test socket;
wherein the device under test socket is coupled to the carrier structure,
wherein the device-under-test socket is configured to establish an electrical contact with an inner surface of the angled device under test or with a connector which is arranged on the inner surface of the angled device under test, and wherein the device-under-test socket is configured to position the angled device-under-test
such that a surface normal of a first outer surface of the angled device-under-test is parallel, within a tolerance of +/−15 degrees, to the surface of the loadboard, and
such that a second outer surface of the angled device under test is facing away from the loadboard, and
such that a surface normal of the second outer surface of the angled device-under-test is perpendicular, within a tolerance of +/−15 degrees, to the surface of the loadboard;
wherein the carrier structure comprises an opening extending away from the device-under-test socket in a direction of an outward surface normal of the first outer surface of the angled device-under-test.
